(19) United States
(12) Patent Application Publication
(10) Pub. No.: US 2026/0218020 A1
(43) Pub. Date: Jul. 30, 2026

(54) RESIN COMPOSITION, FILM, FILM SET, OPTICAL WAVEGUIDE, OPTO-ELECTRIC COMPOSITE SUBSTRATE, AND ELECTRONIC COMPONENT

(71) Applicant: SUMITOMO BAKELITE CO., LTD., Shinagawa-ku, Tokyo (JP)

(72) Inventors: Yuma Tanaka, Tokyo (JP); Kenta Sato, Tokyo (JP); Yuna Matsubara, Tokyo (JP)

(21) Appl. No.: 19/157,396

(22) PCT Filed: Mar. 27, 2024
(86) PCT No.: PCT/JP2024/012202

§ 371 Date: Aug. 18, 2025

(30) Foreign Application Priority Data
Mar. 31, 2023 (JP) 2023-057397

(51) Int. Cl. C09J 163/00; C08J 5/12; C09J 135/00; C09J 145/00; C09J 179/08; G02B 6/12

(52) U.S. Cl. CPC C09J 163/00; C08J 5/125; C09J 135/00; C09J 145/00; C09J 179/08; G02B 6/12; C08J 2367/02; C08J 2435/00; C08J 2445/00; C08J 2463/00; C08J 2479/08

(57) ABSTRACT

A resin composition that can be used for an optical waveguide cladding, in which a flow ratio of a resin layer formed from the resin composition as calculated by the following Method 1 is equal to or more than 6% and equal to or less than 200%. [Method 1] A sample is formed such that a thickness of the resin layer formed from the resin composition is 100 μm, the sample is cut into a circle having a diameter of 1 cm to obtain a sample for measuring a flow ratio. The sample for measuring a flow ratio is sandwiched between slide glasses and laminated using a laminating machine under conditions of a temperature of 100° C., a pressure of 5.0 MPa, and a time of 180 seconds, areas of the resin layer before and after lamination are measured, and the flow ratio [%] is calculated from the following Expression (I):

$$Flow ratio [ \% ] = [ ( Area of resin layer after lamination - Area of resin layer before lamination ) / Area of resin layer before lamination ] \times 100. \qquad ( I )$$

### TECHNICAL FIELD

The present invention relates to a resin composition, a film, a film set, an optical waveguide, an opto-electric composite substrate, and an electronic component.

### BACKGROUND ART

In recent years, in information and communication devices, there is a demand for a member capable of realizing more advanced information and communication, such as an increase in the capacity of information and an increase in the speed of information and communication, and an opto-electric composite substrate has been studied as one of such members.

Examples of the opto-electric composite substrate include one in which an optical waveguide is provided on a substrate.

Examples of the technology for the optical waveguide include the technologies described in Patent Documents 1 to 3.

Patent Document 1 describes an optical waveguide formed by laminating a core layer made of a polymer and a cladding layer made of a polymer on a substrate, in which the core layer is interposed between cladding layers in a direction perpendicular to the surface of the substrate, the cladding layers having a refractive index smaller than that of cladding layers interposing the core layer in a direction parallel to the surface of the substrate.

According to the optical waveguide described in Patent Document 1, it is described that an optical waveguide having a small PDL, which is easy to produce and has a low loss, can be provided even in a case where a polyimide having a large birefringence is used, and an optical integrated circuit or an optical module having excellent characteristics can be provided by using the waveguide.

Patent Document 2 describes an opto-electric hybrid board including: a flexible circuit board which has a mounting pad on the front surface of an insulating layer and in which electrical interconnects are formed; an element mounted on the mounting pad; and an optical waveguide laminated on the back surface side of the insulating layer, in which the flexible circuit board is a flexible double-sided circuit board in which electrical interconnects are also formed on the back surface of the insulating layer, a metal reinforcing layer is formed by plating on at least a portion corresponding to the mounting pad among the electrical interconnects on the back surface side, and the optical waveguide is in a state of being in contact with the metal reinforcing layer.

According to the opto-electric hybrid board described in Patent Document 2, it is disclosed that an opto-electric hybrid board in which a metal reinforcing layer is closely attached to the insulating layer of the flexible circuit board without an adhesive layer, and an element is appropriately mounted in a state where deformation due to a pressing load during element mounting is suppressed by the metal reinforcing layer, can be provided.

Patent Document 2 describes a point that a base material in which a copper foil 21 is formed on front and back surfaces of an insulating layer 1 made of a resin such as a polyimide is prepared, and through-holes 1a and via holes 1b for an optical path are formed in the base material (see paragraph 0023 of Patent Document 2). Then, the flexible double-sided circuit board E on which a metal reinforcing layer M is formed is described (see paragraph 0028 of Patent Document 2). The flexible double-sided circuit board E includes the above-described base material.

In addition, Patent Document 2 describes that an under-cladding layer 6 is formed on the back surface side of the flexible double-sided circuit board E in a state of being in contact with the metal reinforcing layer M that covers the electrical interconnects 2B on the back surface side, and that examples of a molding material for the under-cladding layer 6 include a photosensitive resin and a thermosetting resin (see paragraph 0029 of Patent Document 2). According to FIG. 4 to FIG. 6 of Patent Document 2, it can be understood that the molding material of the under-cladding layer 6 is filled in the recess parts formed in the flexible double-sided circuit board E on which the metal reinforcing layer M is formed.

Patent Document 3 describes an opto-electric wiring board formed by integrating a rigid part in which a conductor circuit and an insulating layer are laminated and formed on both surfaces of a substrate, with one or a plurality of bendable flexible parts, in which an external connection terminal for installing an optical element and/or a package substrate having an optical element mounted thereon is formed in the rigid part, and optical interconnects are formed in at least one of the flexible parts.

According to the opto-electric wiring board of Patent Document 3, it is described that processing of large-volume information and high-speed processing of information can be suitably carried out without increasing the size of the wiring board.

It is described that the rigid part described in Patent Document 3 has an optical signal transmitting region formed therein, and the inside of the optical signal transmitting region is filled with a resin composition (see claims 4 and 5 of Patent Document 3). In addition, it is described that the optical signal transmitting region is formed so as to penetrate through all the substrates and insulating layers constituting the rigid part (see claim 6 of Patent Document 3).

In addition, Patent Document 3 describes a substrate 221 composed of an optical waveguide film 250 and a resin layer (insulating layer) 221a around the optical waveguide film 250, and describes that the resin layer 221a constitutes a part of the optical signal transmitting regions 242a and 242b (see paragraph 0033 of Patent Document 3).

### RELATED DOCUMENT

### Patent Document

[Patent Document 1] Japanese Unexamined Patent Publication No. 2006-119659
[Patent Document 2] Japanese Unexamined Patent Publication No. 2014-238455
[Patent Document 3] Japanese Unexamined Patent Publication No. 2006-140233

### SUMMARY OF THE INVENTION

### Technical Problem

In the technologies related to the conventional opto-electric composite substrates, an opto-electric composite substrate in which recess parts formed in a substrate, and through-holes formed in the substrate are filled with a resin composition, is known (in particular, see Patent Document 2 and Patent Document 3).

Examples of a manufacturing step for an opto-electric composite substrate include a step of integrating a substrate in which vias are formed and a film for an optical waveguide cladding. In this step, it is necessary to fill the vias formed in the substrate with the optical waveguide cladding. That is, the resin composition and the film that can be used for optical waveguide cladding are required to have characteristics that enable the optical waveguide cladding to be sufficiently embedded in the vias (hereinafter, “embedding properties” means characteristics of how much the optical waveguide cladding can be embedded in the vias).

The present invention has been made in view of the above-described circumstances, and provides a resin composition and a film, which make it possible to obtain an optical waveguide cladding with improved embedding properties.

### Solution to Problem

According to the present invention, the following resin composition, film, film set, optical waveguide, opto-electric composite substrate, and electronic component are provided.

[1]

A resin composition that can be used for an optical waveguide cladding,
in which a flow ratio of a resin layer formed from the resin composition as calculated by the following Method 1 is equal to or more than 6% and equal to or less than 200%:

### Method 1

a sample is formed such that a thickness of the resin layer formed from the resin composition is 100 μm, the sample is cut into a circle having a diameter of 1 cm to obtain a sample for measuring a flow ratio,
the sample for measuring a flow ratio is sandwiched between slide glasses and laminated using a laminating machine under conditions of a temperature of 100° C., a pressure of 5.0 MPa, and a time of 180 seconds,
areas of the resin layer before and after lamination are measured, and the flow ratio [%] is calculated from the following Expression (I):

$$Flow ratio [ \% ] = [ ( Area of resin layer after lamination - Area of resin layer before lamination ) / Area of resin layer before lamination ] \times 100. \qquad ( I )$$

[2]

The resin composition according to [1],
in which a storage elastic modulus E′ at 100° C. of a cured product formed from the resin composition is equal to or more than 0.5 GPa and equal to or less than 5.0 GPa.
   [3]

The resin composition according to [1] or [2],
in which a storage elastic modulus E′ at 200° C. of a cured product formed from the resin composition is equal to or more than 0.1 GPa and equal to or less than 3.0 GPa.
   [4]

The resin composition according to any one of [1] to [3],
in which a glass transition temperature of a cured product formed from the resin composition, which is calculated from a top peak of tan δ by a dynamic viscoelasticity analyzer (DMA), is equal to or higher than 150° C. and equal to or lower than 400° C.
   [5]

The resin composition according to any one of [1] to [4], containing:
a polyimide resin (A); and
a compound (B) having a cyclic ether structure.
   [6]

The resin composition according to any one of [1] to [4], containing:
a resin (F) having a norbornene skeleton; and
a compound (B) having a cyclic ether structure.
   [7]

The resin composition according to [5] or [6], further containing:
a curing agent (C).
   [8]

A film that can be used for an optical waveguide cladding, the film including:
a resin layer,
in which a flow ratio of the resin layer as calculated by the following Method 2 is equal to or more than 6% and equal to or less than 200%:

### Method 2

a sample is formed such that a thickness of the resin layer is 100 μm, the sample is cut into a circle having a diameter of 1 cm to obtain a sample for measuring a flow ratio,
the sample for measuring a flow ratio is sandwiched between slide glasses and laminated using a laminating machine under conditions of a temperature of 100° C., a pressure of 5.0 MPa, and a time of 180 seconds,
areas of the resin layer before and after lamination are measured, and the flow ratio [%] is calculated from the following Expression (I):

$$Flow ratio [ \% ] = [ ( Area of resin layer after lamination - Area of resin layer before lamination ) / Area of resin layer before lamination ] \times 100. \qquad ( I )$$

[9]

The film according to [8],
in which a storage elastic modulus E′ at 100° C. of a cured product obtained by curing the resin layer is equal to or more than 0.5 GPa and equal to or less than 5.0 GPa.
   [10]

The film according to [8] or [9],
in which a storage elastic modulus E′ at 200° C. of a cured product obtained by curing the resin layer is equal to or more than 0.1 GPa and equal to or less than 3.0 GPa.
   [11]

The film according to any one of [8] to [10],
in which a glass transition temperature of a cured product obtained by curing the resin layer, which is calculated from a top peak of tan δ by a dynamic viscoelasticity analyzer (DMA), is equal to or higher than 150° C. and equal to or lower than 400° C.
   [12]

The film according to any one of [8] to [11], further including:
a base material film,
in which the resin layer is provided on the base material film.
   [13]

The film according to [12],
in which a resin constituting the base material film contains at least one kind or two or more kinds selected from the group consisting of a polyimide and polyethylene terephthalate.
   [14]

The film according to any one of [8] to [13],
in which the film is a dry film.
   [15]

A film set that can be used for an optical waveguide cladding, the film set including:
a first film; and
a second film,
in which at least one of the first film and the second film is the film according to any one of [8] to [14].
   [16]

An optical waveguide including:
a first cladding layer;
a core layer; and
a second cladding layer,
in which the first cladding layer, the core layer, and the second cladding layer are laminated in this order, and
at least one of the first cladding layer and the second cladding layer contains the resin composition according to any one of [1] to [7].
   [17]

An opto-electric composite substrate including:
a substrate; and
the optical waveguide according to provided on the substrate.
   [18]

An electronic component including:
the opto-electric composite substrate according to.

### Advantageous Effects of Invention

According to the present invention, a resin composition and a film, which make it possible to obtain an optical waveguide cladding with improved embedding properties, can be provided.

### BRIEF DESCRIPTION OF THE DRAWINGS

FIG. 1 shows a cross-sectional view schematically illustrating an example of the structure of an opto-electric composite substrate of the present embodiment.

### DESCRIPTION OF EMBODIMENTS

Hereinafter, embodiments of the present invention will be described using the drawings. Furthermore, unless particularly stated otherwise, “A to B” in a numerical value range indicates a range of equal to or more than A and equal to or less than B.

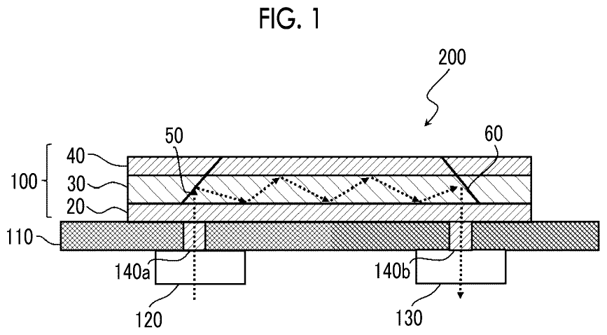

FIG. 1 is a cross-sectional view schematically showing an example of the structure of an opto-electric composite substrate of the present embodiment. The drawing is a schematic diagram, and dimensional ratios thereof do not necessarily match actual dimensional ratios.

As shown in FIG. 1, an opto-electric composite substrate 200 includes an optical waveguide 100 provided on a substrate 110. In the optical waveguide 100, a first cladding layer 20, a core layer 30, and the second cladding layer 40 are laminated in this order. In the optical waveguide 100, a mirror 50 on the light emitting element side and a mirror 60 on the light receiving element side are formed. In the substrate 110, vias 140 (140a and 140b) are formed (the vias 140 shown in FIG. 1 are in a state of being embedded in the first cladding layer 20). A light emitting element 120 and a light receiving element 130 are provided on the substrate 110 on the opposite side of the optical waveguide 100 side.

When the optical waveguide 100 is provided on the substrate 110, for example, a step of laminating the substrate 110 in which the vias 140 have been formed and a film for forming the first cladding layer 20, and integrating the substrate and the film by heating and pressurizing, is included. In the integrating step, the vias 140 need to be embedded by the first cladding layer 20.

According to the studies conducted by the present inventors, it was found that when the materials for forming conventional optical waveguide claddings are used, the optical waveguide cladding cannot sufficiently fill the vias formed in the substrate, and depressions may be formed on a surface of the optical waveguide cladding on the opposite side of the substrate side (that is, the core layer side of the optical waveguide cladding), or voids may be generated inside the vias. Then, it was found that when the above-mentioned depressions and voids are generated in the opto-electric composite substrate, optical loss occurs at the interface of the depressions and voids.

The present invention has been made in view of the above-described circumstances, and provides a resin composition and a film, which make it possible to obtain an optical waveguide cladding with improved embedding properties.

The propagation path of light in the opto-electric composite substrate 200 will be specifically described using FIG. 1. The light emitted from the light emitting part of the light emitting element 120 passes through the vias 140a formed in the substrate 110, enters the mirror 50 on the light emitting element side, whereby it is transmitted through the core layer 30, enters the mirror 60 on the light receiving element side, passes through the vias 140b formed in the substrate 110, and enters the light receiving element 130. The arrows in FIG. 1 schematically describe the propagation of light.

When an opto-electric composite substrate is mounted on an electronic component, for example, a step of exposing the opto-electric composite substrate to a high temperature (for example, 230° C. to 270° C.), such as a reflow soldering process, may be included. According to the studies conducted by the present inventors, it was found that in the conventional opto-electric composite substrates, the optical waveguide may undergo thermal contraction when the opto-electric composite substrate is exposed to a high temperature. It was found that positional shift of the mirrors may occur when such thermal contraction of the optical waveguide occurs. Then, it was found that when positional shift of the mirrors occurs, light cannot propagate along the assumed optical path, and normal light propagation cannot occur.

In addition, according to the present invention, a resin composition and a film, which make it possible to obtain an optical waveguide in which thermal contraction is suppressed, can be provided.

### [Resin Composition]

A resin composition of the present embodiment is a resin composition that can be used for an optical waveguide cladding, and a flow ratio of a resin layer formed from the resin composition, which is calculated by Method 1, is equal to or more than 6% and equal to or less than 200%.

### Method 1

A sample is formed such that a thickness of a resin layer formed from a resin composition is 100 μm, the sample is cut into a circle having a diameter of 1 cm to obtain a sample for measuring a flow ratio, the sample for measuring a flow ratio is sandwiched between slide glasses and laminated using a laminating machine under conditions of a temperature of 100° C., a pressure of 5.0 MPa, and a time of 180 seconds, areas of the resin layer before and after lamination are measured, and the flow ratio [%] is calculated from the following Expression (I).

$$Flow ratio [ \% ] = [ ( Area of resin layer after lamination - Area of resin layer before lamination ) / Area of resin layer before lamination ] \times 100 \qquad ( I )$$

Here, a method for forming a sample such that the thickness of the resin layer formed from the resin composition in the method 1 is 100 μm is not particularly limited, and for example, the following methods may be mentioned.

In a case where the resin composition is in the form of a film, for example, a method of obtaining a sample by laminating a film-like resin composition using a laminating machine such that the thickness of the resin layer is 100 μm, may be mentioned. Furthermore, in a case where the thickness of the film-like resin composition is more than 100 μm, a sample can also be obtained by cutting the film-like resin composition so as to have a thickness of 100 μm.

In a case where the resin composition is in the form of a varnish, for example, a method of applying a varnish-like resin composition on a base material film, drying the varnish-like resin composition to obtain a film-like resin composition, and then obtaining a sample by the above-described method, may be mentioned.

Among these, as a method of forming a sample such that the thickness of the resin layer formed from the resin composition in Method 1 is 100 μm, the method described in the Examples is preferred.

As described above, there is a demand for a resin composition that makes it possible to obtain an optical waveguide cladding with improved embedding properties.

Here, the present inventors found for the first time that embedding properties is improved by setting the flow ratio of a resin composition calculated by Method 1 to a specific range.

From the viewpoint of further improving the embedding properties, the flow ratio of the resin composition of the present embodiment calculated by Method 1 is preferably equal to or more than 10%, more preferably equal to or more than 13%, even more preferably equal to or more than 15%, and still more preferably equal to or more than 18%, and from the viewpoint of preventing contamination when manufacturing an optical waveguide and adjusting the thickness of the cladding layer of the optical waveguide to an appropriate thickness, the flow ratio is preferably equal to or less than 190%, more preferably equal to or less than 180%, even more preferably equal to or less than 150%, still more preferably equal to or less than 100%, even more preferably equal to or less than 90%, still more preferably equal to or less than 80%, and even more preferably equal to or less than 70%.

The flow ratio of the resin composition can be adjusted to a desired numerical value range by, for example, adjusting the type, weight average molecular weight (Mw), and glass transition temperature of the resin constituting the resin composition, the content proportions of the constituent components of the resin composition, and the like.

The storage elastic modulus E′ at 100° C. of a cured product formed from the resin composition of the present embodiment is preferably equal to or more than 0.5 GPa, more preferably equal to or more than 0.8 GPa, even more preferably equal to or more than 1.0 GPa, still more preferably equal to or more than 1.2 GPa, even more preferably equal to or more than 1.5 GPa, and still more preferably equal to or more than 1.7 GPa, and from the viewpoint of further improving the embedding properties, the storage elastic modulus E′ is preferably equal to or less than 5.0 GPa, more preferably equal to or less than 4.5 GPa, even more preferably equal to or less than 4.0 GPa, still more preferably equal to or less than 3.5 GPa, and even more preferably equal to or less than 3.2 GPa.

From the viewpoint of further suppressing thermal contraction of the optical waveguide, the storage elastic modulus E′ at 200° C. of a cured product formed from the resin composition of the present embodiment is preferably equal to or more than 0.1 GPa, more preferably equal to or more than 0.2 GPa, and even more preferably equal to or more than 0.3 GPa, and the upper limit value is not particularly limited, but may be, for example, equal to or less than 3.0 GPa or may be equal to or less than 2.0 GPA.

The storage elastic moduli E′ at 100° C. and 200° C. of a cured product formed from the resin composition of the present embodiment can be adjusted to desired numerical value ranges by, for example, adjusting the type, weight average molecular weight (Mw), and glass transition temperature of the resin constituting the resin composition, the content proportions of the constituent components of the resin composition, and the like.

From the viewpoint of further suppressing thermal contraction of the optical waveguide, the glass transition temperature (Tg) of a cured product formed from the resin composition of the present embodiment is preferably equal to or higher than 150° C., more preferably equal to or higher than 160° C., and even more preferably equal to or higher than 180° C., and the upper limit value is not particularly limited, but is, for example, equal to or lower than 400° C.

Here, the glass transition temperature (Tg) means a glass transition temperature calculated from a top peak of tan δ by a dynamic viscoelasticity analyzer (DMA).

The storage elastic modulus E′ at 100° C., the storage elastic modulus E′ at 200° C., and the glass transition temperature (Tg) of a cured product formed from the above-described resin composition can be calculated by the methods described in the Examples.

Specifically, a cured product formed from the resin composition is heated from 30° C. to 400° C. using a dynamic viscoelasticity analyzer in a nitrogen atmosphere under the conditions of a frequency of 1 Hz, tensile mode, a distance between samples of 1 cm, a sample width of 1 cm, and a temperature increase rate of 5° C./min, and the storage elastic modulus E′ and tan δ with respect to temperature are measured. From the obtained storage elastic modulus E′, the storage elastic moduli E′ at 100° C. and 200° C. of a cured product formed from the resin composition are calculated. Furthermore, the glass transition temperature (Tg) of a cured product formed from the resin composition is calculated from the obtained top peak of tan δ.

Here, the cured product formed from the resin composition means a cured product in a state in which the resin composition is completely cured (C stage).

As a method for determining whether a cured product is in a state in which the resin composition is completely cured (C stage), for example, a method of checking, by Fourier transform infrared spectroscopy (FT-IR method), whether an increase or decrease in the intensity of a peak originating from a functional group involved in a curing reaction (for example, a CO group in a cyclic ether structure) is constant, may be mentioned.

The method for curing the resin composition is not particularly limited, and examples thereof include a method of heating the resin composition, a method of irradiating the resin composition with light, and a method of irradiating the resin composition with light while heating the resin composition; however, preferred is a method of heating the resin composition in the atmosphere at 180° C. for 2 hours. Furthermore, the method of irradiating the resin composition with light is preferably a method of exposing the resin composition to light using a high-pressure mercury lamp under the conditions of a cumulative light amount of 1,000 mJ/cm².

The shape of the resin composition of the present embodiment is not particularly limited, and examples thereof include shapes such as a film shape, a membrane shape, a varnish shape, and a sheet shape.

The resin composition of the present embodiment is preferably a semi-cured product or an uncured product, and more preferably a semi-cured product.

The constituent components of the resin composition of the present embodiment are not particularly limited; however, the constituent components preferably include a polyimide resin (A) and a compound (B) having a cyclic ether structure, and more preferably include a polyimide resin (A), a compound (B) having a cyclic ether structure, and a curing agent (C).

Furthermore, as another preferred aspect, the resin composition of the present embodiment preferably contains a resin (F) having a norbornene skeleton and a compound (B) having a cyclic ether structure, and more preferably contains a resin (F) having a norbornene skeleton, a compound (B) having a cyclic ether structure, and a curing agent (C).

Each preferred constituent component of the resin composition of the present embodiment will be described below.

### <Polyimide Resin (A)>

From the viewpoint of further improving the embedding properties, when the total content of the resin components in the resin composition is set to 100 parts by mass, the content of the polyimide resin (A) contained in the resin composition of the present embodiment is preferably equal to or more than 20 parts by mass, more preferably equal to or more than 23 parts by mass, even more preferably equal to or more than 25 parts by mass, and still more preferably equal to or more than 28 parts by mass, and from the viewpoint of further improving the embedding properties, the content is preferably equal to or less than 80 parts by mass, more preferably equal to or less than 75 parts by mass, even more preferably equal to or less than 70 parts by mass, and still more preferably equal to or less than 65 parts by mass.

From the viewpoint of suppressing voids and the like due to volatile components, it is preferable that the polyimide resin (A) according to the present embodiment contains an imide ring structure in the molecule. The present inventors believe that when an imide ring structure is contained in the molecule, the generation of volatile components (for example, moisture) can be suppressed when curing the resin composition, and therefore, voids and the like originating from volatile components in the vias can be suppressed.

The imidization ratio of the polyimide resin (A) according to the present embodiment is preferably equal to or more than 90%, more preferably equal to or more than 93%, even more preferably equal to or more than 95%, still more preferably equal to or more than 97%, even more preferably equal to or more than 98%, and still more preferably equal to or more than 99%.

The imidization ratio of the polyimide resin (A) means an imidization ratio expressed by {IM/(IM+AM)}×100(%), when the number of moles of imide groups contained in the polyimide resin (A) is denoted as IM, and the number of moles of amide groups contained in the polyimide resin (A) is denoted as AM.

The imidization ratio can be determined from, for example, the area of the peak corresponding to the amide group and the area of the peak corresponding to the imide group in the NMR spectrum, or the like. As another example, the imidization ratio can be determined from the area of the peak corresponding to the amide group and the area of the peak corresponding to the imide group in the infrared absorption spectrum, and the like.

It is preferable that the polyimide resin (A) according to the present embodiment includes a fluorinated polyimide. The fluorinated polyimide means a polyimide containing fluorine atoms.

When the polyimide resin (A) according to the present embodiment includes a fluorinated polyimide, the solubility in an organic solvent is further improved, and therefore, it is easy to obtain a varnish-like resin composition.

From the viewpoint of further improving the solubility in an organic solvent, the amount (mass ratio) of fluorine atoms in the fluorinated polyimide is preferably equal to or more than 1% by mass, more preferably equal to or more than 3% by mass, and even more preferably equal to or more than 5% by mass, and is preferably equal to or less than 30% by mass, more preferably equal to or less than 28% by mass, and even more preferably equal to or less than 25% by mass.

It is preferable that the fluorinated polyimide according to the present embodiment contains a structural unit represented by the following General Formula (a).

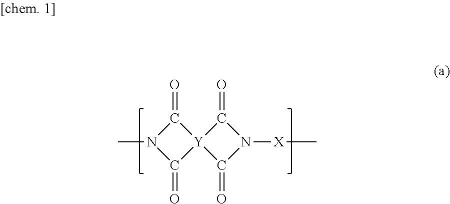

In General Formula (a), X is a divalent organic group, Y is a tetravalent organic group, and at least one of X and Y has a fluorine atom.

In General Formula (a), from the viewpoint of further suppressing thermal contraction of the optical waveguide, it is preferable that the divalent organic group of X and/or the tetravalent organic group of Y contains an aromatic ring structure, and more preferably a benzene ring structure.

In General Formula (a), regarding the divalent organic group of X and/or the tetravalent organic group of Y, from the viewpoint of further improving the solubility in an organic solvent, it is preferable that both X and Y are fluorine atom-containing groups.

In General Formula (a), the divalent organic group of X and/or the tetravalent organic group of Y preferably has a structure in which two to six benzene rings are bonded through a single bond or a divalent linking group. Examples of the divalent linking group as used herein include an alkylene group, a fluorinated alkylene group, and an ether group. The alkylene group and the fluorinated alkylene group may be linear or branched.

In General Formula (a), the number of carbon atoms in the divalent organic group of X is, for example, 6 to 30.

In General Formula (a), the number of carbon atoms in the tetravalent organic group of Y is, for example, 6 to 20.

It is preferable that the two imide rings in General Formula (a) are each a 5-membered ring.

It is more preferable that the fluorinated polyimide according to the present embodiment contains a structural unit represented by the following General Formula (aa).

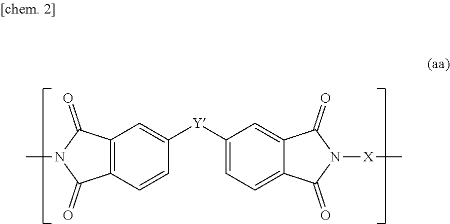

In General Formula (aa), Y′ represents a single bond or an alkylene group, X has the same meaning as X in General Formula (a), and at least one of X and Y′ has a fluorine atom.

In General Formula (aa), the alkylene group of Y′ may be linear or branched. It is preferable that some or all of hydrogen atoms in the alkylene group of Y′ are substituted with fluorine atoms. The number of carbon atoms in the alkylene group of Y′ is preferably 1 to 6, more preferably 1 to 4, and even more preferably 1 to 3.

In General Formula (aa), it is preferable that both X and Y′ are fluorine atom-containing groups.

From the viewpoint of further improving the optical propagation efficiency of the optical waveguide, the refractive index of the polyimide resin (A) according to the present embodiment is preferably equal to or less than 1.58, more preferably equal to or less than 1.56, even more preferably equal to or less than 1.55, and still more preferably equal to or less than 1.54, and the lower limit value is not particularly limited, but is, for example, equal to or more than 1.50.

The refractive index of the polyimide resin (A) means a refractive index measured under the conditions of 23° C. and 589 nm using an Abbe refractometer.

From the viewpoint of further suppressing thermal contraction of the optical waveguide, the weight average molecular weight (Mw) of the polyimide resin (A) according to the present embodiment is preferably equal to or more than 5,000, more preferably equal to or more than 7,000, even more preferably equal to or more than 10,000, still more preferably equal to or more than 30,000, and even more preferably equal to or more than 40,000, and from the viewpoint of further improving the solubility in an organic solvent, the weight average molecular weight (Mw) is preferably equal to or less than 200,000, more preferably equal to or less than 150,000, even more preferably equal to or less than 130,000, and still more preferably equal to or less than 110,000.

The weight average molecular weight can be determined by a gel permeation chromatography (GPC) method using polystyrene as a standard substance.

The polyimide resin (A) according to the present embodiment can be obtained by, for example, (i) first, reacting a diamine with an acid dianhydride (polycondensation reaction) to synthesize a polyamide, and (ii) subsequently, imidizing the polyamide (ring-closing reaction). Specific reaction conditions can be, for example, known conditions.

Examples of the diamine as a raw material for synthesizing the polyimide resin (A) according to the present embodiment include 2,2′-bis(trifluoromethyl)-4,4′-diaminobiphenyl, 2,2-bis[4-(4-aminophenoxy)phenyl]-1,1,1,3,3,3-hexafluoropropane, 3,4′-diaminodiphenyl ether (3,4′-ODA), 4,4′-diamino-2,2′-bis(trifluoromethyl)biphenyl (TFMB), 3,3′,5,5′-tetramethylbenzidine, 2,3,5,6-tetramethyl-1,4-phenylenediamine, 3,3′-diaminodiphenyl sulfone, 3,3′-dimethylbenzidine, 3,3′-bis(trifluoromethyl)benzidine, 2,2′-bis(p-aminophenyl)hexafluoropropane, bis(trifluoromethoxy)benzidine (TFMOB), 2,2′-bis(pentafluoroethoxy)benzidine (TFEOB), 2,2′-trifluoromethyl-4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino-4-methylphenyl)hexafluoropropane, 3,6-bis(trifluoromethyl)-1,4-diaminobenzene (2TFMPDA), 1-(3,5-diaminophenyl)-2,2-bis(trifluoromethyl)-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′,6,6′-tetramethylbenzidine (TMBZ), 3,6-diamino-9,9-bis(trifluoromethyl) xanthene (6FCDAM), 3,6-diamino-9-trifluoromethyl-9-phenylxanthene (3FCDAM), and 3,6-diamino-9,9-diphenylxanthene.

Regarding the diamine, one kind thereof may be used alone, or two or more kinds thereof may be used in combination.

Examples of the acid dianhydride as a raw material for synthesizing the polyimide resin (A) according to the present embodiment include 4,4′-(hexafluoroisopropylidene)diphthalic dianhydride, 4,4′-oxydiphthalic dianhydride, pyromellitic dianhydride (PMDA), diphenyl ether-3,3′,4,4′-tetracarboxylic acid dianhydride (ODPA), benzophenone-3,3′,4,4′-tetracarboxylic acid dianhydride (BTDA), biphenyl-3,3′,4,4′-tetracarboxylic acid dianhydride (BPDA), diphenylsulfone-3,3′,4,4′-tetracarboxylic acid dianhydride (DSDA), diphenylmethane-3,3′,4,4′-tetracarboxylic acid dianhydride, 2,2-bis(3,4-phthalic anhydride) propane, and 2,2-bis(3,4-phthalic anhydride)-1,1,1,3,3,3-hexafluoropropane (6FDA).

Regarding the acid dihydride, one kind thereof may be used alone, or two or more kinds thereof may be used in combination.

The polyimide resin (A) according to the present embodiment may be a polyimide resin of one kind, or may include two or more kinds of polyimide resins.

<Compound (B) having Cyclic Ether Structure>

The compound (B) having a cyclic ether structure according to the present embodiment preferably includes at least one kind or two or more kinds selected from the group consisting of an epoxy resin and an oxetane compound, and more preferably includes one kind or two or more kinds of epoxy resins.

Here, as the compound having a cyclic ether structure according to the present embodiment, a monomer, an oligomer, or a polymer in general can be used, and the molecular weight and the molecular structure thereof are not particularly limited. Furthermore, it should be noted that, in the present specification, the resin component in the resin composition also includes the compound (B) having a cyclic ether structure.

From the viewpoint of further improving the embedding properties, when the total content of the resin components in the resin composition is set to 100 parts by mass, the content of the compound (B) having a cyclic ether structure contained in the resin composition of the present embodiment is preferably equal to or more than 20 parts by mass, more preferably equal to or more than 25 parts by mass, even more preferably equal to or more than 30 parts by mass, and still more preferably equal to or more than 35 parts by mass, and from the viewpoint of further improving the embedding properties, the content is preferably equal to or less than 80 parts by mass, and more preferably equal to or less than 75 parts by mass.

It is preferable that the compound (B) having a cyclic ether structure according to the present embodiment contains an alicyclic structure in the molecule. Here, when it is said that the compound (B) having a cyclic ether structure contains an alicyclic structure in the molecule, it means that the compound (B) contains an alicyclic structure in addition to the cyclic ether structure. However, it should be noted that the alicyclic structure according to the present embodiment includes a fused ring structure in which a cyclic ether and an aliphatic ring are fused, and a spiro ring structure in which a cyclic ether and an aliphatic ring are bonded by a spiro-bonded atom.

The number of ring members in the alicyclic structure is not particularly limited; however, the ring is preferably a ring with equal to or more than 4 ring members and equal to or fewer than 10 ring members, more preferably a ring with equal to or more than 4 ring members and equal to or fewer than 8 ring members, even more preferably a 5-membered ring or a 6-membered ring, and still more preferably a 6-membered ring.

It is preferable that the compound (B) having a cyclic ether structure according to the present embodiment contains equal to or more than two cyclic ether structures in the molecule, and it is more preferable that the compound (B) contains two or three cyclic ether structures in the molecule.

From the viewpoint of handleability when manufacturing the resin composition, it is preferable that the compound (B) having a cyclic ether structure according to the present embodiment is in a liquid state at 23° C.

From the viewpoint of further improving the optical propagation efficiency of the optical waveguide, the refractive index of the compound (B) having a cyclic ether structure according to the present embodiment is preferably equal to or less than 1.55, more preferably equal to or less than 1.53, and even more preferably equal to or less than 1.52, and the lower limit value is not particularly limited, but is, for example, equal to or more than 1.45.

The refractive index of the compound (B) having a cyclic ether structure means a refractive index measured under the conditions of 23° C. and 589 nm using an Abbe refractometer.

The compound (B) having a cyclic ether structure according to the present embodiment may be one kind of compound having a cyclic ether structure, or may include two or more kinds of compound having a cyclic ether structures.

### <Curing Agent (C)>

As the curing agent (C) according to the present embodiment, for example, a thermal polymerization initiator, a photopolymerization initiator, or an amine-based compound can be used.

The content of the curing agent (C) in the resin composition of the present embodiment is, when the total content of the resin components in the resin composition is set to 100 parts by mass, preferably equal to or more than 0.1 parts by mass, more preferably equal to or more than 0.3 parts by mass, even more preferably equal to or more than 0.5 parts by mass, still more preferably equal to or more than 0.7 parts by mass, and even more preferably equal to or more than 1.0 part by mass, and is preferably equal to or less than 10.0 parts by mass, more preferably equal to or less than 8.0 parts by mass, even more preferably equal to or less than 6.0 parts by mass, and still more preferably equal to or less than 5.5 parts by mass.

It is preferable that the curing agent (C) according to the present embodiment includes a cationic polymerization initiator.

Examples of the cationic polymerization initiator include a thermal cationic polymerization initiator and a photocationic polymerization initiator, and among these, a thermal cationic polymerization initiator is preferred.

The thermal cationic polymerization initiator includes, for example, a sulfonium salt-type polymerization initiator and an iodonium salt-type polymerization initiator, and preferably includes a sulfonium salt-type polymerization initiator.

The photocationic polymerization initiator includes, for example, a sulfonium salt-type polymerization initiator and an iodonium salt-type polymerization initiator, and preferably includes a sulfonium salt-type polymerization initiator.

In the curing agent (C) according to the present embodiment, a thermal cationic polymerization initiator and a photocationic polymerization initiator may be used in combination.

It is preferable that the curing agent (C) according to the present embodiment includes an imidazole-based compound. The imidazole-based compound means a compound containing an imidazole ring structure, and is, for example, a compound in which hydrogen of imidazole is substituted with a hydrocarbon group or the like.

The curing agent (C) according to the present embodiment may be one kind of curing agent, or may include two or more kinds of curing agents.

### <Surfactant (D)>

From the viewpoint of further improving the embedding properties, it is preferable that the resin composition according to the present embodiment further contains a surfactant (D).

The surfactant (D) includes, for example, a silicone-based surfactant and a fluorine-based surfactant, and preferably includes a silicone-based surfactant.

The surfactant (D) according to the present embodiment may be one kind of surfactant, or may include two or more kinds of surfactants.

When the total content of the resin components in the resin composition is set to 100 parts by mass, the content of the surfactant (D) contained in the resin composition of the present embodiment is preferably equal to or more than 0.01 parts by mass, more preferably equal to or more than 0.05 parts by mass, and even more preferably equal to or more than 0.07 parts by mass, and is preferably equal to or less than 3.0 parts by mass, more preferably equal to or less than 1.0 part by mass, even more preferably equal to or less than 0.7 parts by mass, still more preferably equal to or less than 0.5 parts by mass, and even more preferably equal to or less than 0.3 parts by mass.

### <Organic Solvent (E)>

The resin composition of the present embodiment may contain an organic solvent (E). When the resin composition of the present embodiment contains the organic solvent (E), the resin composition can be made into a varnish-like resin composition.

Examples of the organic solvent (E) of the present embodiment include acetone, methyl ethyl ketone, toluene, propylene glycol monomethyl ether, propylene glycol methyl ethyl ether, propylene glycol dimethyl ether, propylene glycol 1-monomethyl ether 2-acetate, diethylene glycol ethyl methyl ether, diethylene glycol monoethyl ether acetate, diethylene glycol monobutyl ether acetate, benzyl alcohol, propylene carbonate, ethylene glycol diacetate, propylene glycol diacetate, propylene glycol monomethyl ether acetate, dipropylene glycol methyl n-propyl ether, butyl acetate, γ-butyrolactone, methyl lactate, ethyl lactate, and butyl lactate.

The organic solvent (E) according to the present embodiment may be a single organic solvent, or may include two or more kinds of organic solvents.

When the resin composition of the present embodiment contains the organic solvent (E), from the viewpoint of appropriately controlling the viscosity of the resin composition, the concentration of the total solid content (non-volatile components) in the resin composition is preferably equal to or more than 10% by mass, more preferably equal to or more than 20% by mass, even more preferably equal to or more than 30% by mass, and still more preferably equal to or more than 35% by mass, and from the viewpoint of sufficiently dissolving each component in the resin composition, the concentration is preferably equal to or less than 60% by mass, more preferably equal to or less than 55% by mass, and even more preferably equal to or less than 50% by mass.

<Resin (F) having Norbornene Skeleton>

From the viewpoint of further improving the embedding properties, when the total content of the resin components in the resin composition is set to 100 parts by mass, the content of the resin (F) having a norbornene skeleton contained in the resin composition of the present embodiment is preferably equal to or more than 20 parts by mass and equal to or less than 95 parts by mass, more preferably equal to or more than 30 parts by mass and equal to or less than 90 parts by mass, and even more preferably equal to or more than 35 parts by mass and equal to or less than 85 parts by mass.

The resin (F) having a norbornene skeleton preferably contains a structural unit represented by Formula (1).

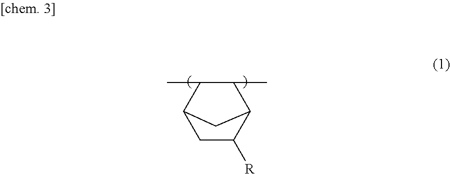

In Formula (1), R represents a hydrogen atom, a hydroxyl group, or an organic group having equal to or more than 1 carbon atom and equal to or fewer than 30 carbon atoms.

In Formula (1), the organic group constituting R is, for example, any one selected from the group consisting of an alkyl group, an alkenyl group, an alkynyl group, an alkylidene group, an aryl group, an aralkyl group, an alkaryl group, a cycloalkyl group, and an organic group having a carboxyl group.

In Formula (1), the organic group constituting R preferably excludes a group having a cyclic ether structure.

Examples of the alkyl group include at least one selected from the group consisting of a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, an octyl group, a nonyl group, and a decyl group.

Examples of the alkenyl group include at least one selected from the group consisting of an allyl group, a pentenyl group, and a vinyl group.

Examples of the alkynyl group include an ethynyl group.

Examples of the alkylidene group include at least one selected from the group consisting of a methylidene group and an ethylidene group.

Examples of the aryl group include at least one selected from the group consisting of a phenyl group, a naphthyl group, and an anthracenyl group.

Examples of the aralkyl group include at least one selected from the group consisting of a benzyl group and a phenethyl group.

Examples of the alkaryl group include at least one selected from the group consisting of a tolyl group and a xylyl group.

Examples of the cycloalkyl group include at least one selected from the group consisting of an adamantyl group, a cyclopentyl group, a cyclohexyl group, and a cyclooctyl group.

In the organic group constituting R in Formula (1), the organic groups having an alkyl group, an alkenyl group, an alkynyl group, an alkylidene group, an aryl group, an aralkyl group, an alkaryl group, a cycloalkyl group, and a carboxyl group may have one or more hydrogen atoms substituted with a halogen atom. Examples of the halogen atom include fluorine, chlorine, bromine, and iodine.

In Formula (1), R is preferably any one selected from the group consisting of a hydrogen atom and an alkyl group, more preferably any one selected from the group consisting of a hydrogen atom and an alkyl group having equal to or more than 1 carbon atom and equal to or fewer than 10 carbon atoms, and even more preferably an alkyl group having equal to or more than 3 carbon atoms and equal to or fewer than 7 carbon atoms.

In Formula (1), when R is an alkyl group, the coating properties of the resin composition can be further improved.

The resin (F) having a norbornene skeleton preferably contains a structural unit represented by Formula (2).

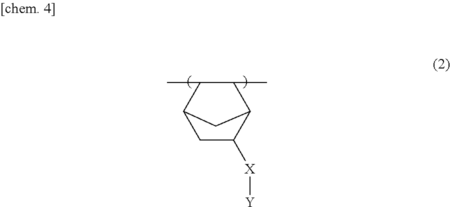

In Formula (2), X is a divalent organic group having equal to or more than 1 carbon atom and equal to or fewer than 30 carbon atoms, and Y represents a group having a cyclic ether structure.

In Formula (2), the divalent organic group having equal to or more than 1 carbon atom and equal to or fewer than 30 carbon atoms is preferably a group containing an oxygen atom.

In Formula (2), the divalent organic group having equal to or more than 1 carbon atom and equal to or fewer than 30 carbon atoms preferably has equal to or more than 1 carbon atom and equal to or fewer than 20 carbon atoms, more preferably has equal to or more than 1 carbon atom and equal to or fewer than 10 carbon atoms, and even more preferably has equal to or more than 1 carbon atom and equal to or fewer than 5 carbon atoms.

In Formula (2), the group having a cyclic ether structure preferably includes at least one selected from the group consisting of a group containing an epoxy group and a group containing an oxetanyl group.

The structural unit represented by Formula (2) preferably includes a structural unit represented by Formula (2-1).

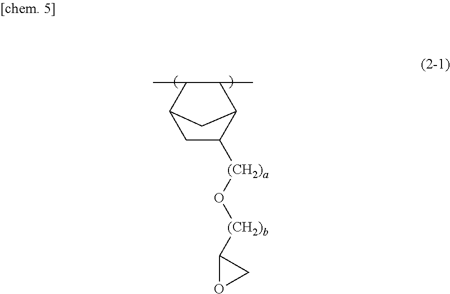

In Formula (2-1), a represents an integer of equal to or more than 0 and equal to or less than 3, and b represents an integer of equal to or more than 1 and equal to or less than 3.

In Formula (2-1), a is preferably 1 or 2, and more preferably 1.

In Formula (2-1), b is preferably 1 or 2, and more preferably 1.

The resin (F) having a norbornene skeleton may contain another structural unit in addition to the structural unit derived from a norbornene-based compound.

The other structural unit includes, for example, at least one selected from the group consisting of a structural unit derived from a maleimide-based compound, a structural unit derived from a compound having an ethylenic double bond, and the like, and preferably includes a structural unit derived from a maleimide-based compound.

The maleimide-based compound includes, for example, at least one selected from the group consisting of maleimide and N-cyclohexylmaleimide, and preferably includes N-cyclohexylmaleimide.

The resin (F) having a norbornene skeleton preferably contains a structural unit represented by Formula (1) and a structural unit represented by Formula (2), and more preferably contains a structural unit represented by Formula (1) and a structural unit represented by Formula (2-1).

When the total sum of all the structural units in the resin (F) having a norbornene skeleton is set to 100 mol %, the content of the structural unit derived from a norbornene-based compound in the resin (F) having a norbornene skeleton is preferably equal to or more than 60 mol %, more preferably equal to or more than 70 mol %, even more preferably equal to or more than 80 mol %, still more preferably equal to or more than 90 mol %, even more preferably equal to or more than 95 mol %, still more preferably equal to or more than 98 mol %, and even more preferably 100 mol %.

Furthermore, as another preferred aspect, the resin (F) having a norbornene skeleton preferably contains a structural unit represented by Formula (1), a structural unit represented by Formula (2), and a structural unit derived from a maleimide-based compound, and more preferably contains a structural unit represented by Formula (1), a structural unit represented by Formula (2-1), and a structural unit derived from a maleimide-based compound.

When the total sum of all the structural units in the resin (F) having a norbornene skeleton is set to 100 mol %, the total content of the structural unit derived from a norbornene-based compound and the structural unit derived from a maleimide-based compound in the resin (F) having a norbornene skeleton is preferably equal to or more than 60 mol %, more preferably equal to or more than 70 mol %, even more preferably equal to or more than 80 mol %, still more preferably equal to or more than 90 mol %, even more preferably equal to or more than 95 mol %, still more preferably equal to or more than 98 mol %, and even more preferably 100 mol %.

From the viewpoint of further improving the optical propagation efficiency of the optical waveguide, the refractive index of the resin (F) having a norbornene skeleton is preferably equal to or less than 1.55, more preferably equal to or less than 1.54, and even more preferably equal to or less than 1.53, and the lower limit value is not particularly limited, but may be, for example, equal to or more than 1.45, or may be equal to or more than 1.48. Furthermore, from the viewpoint of further improving the optical propagation efficiency of the optical waveguide, the refractive index of the resin (F) having a norbornene skeleton is preferably equal to or more than 1.45 and equal to or less than 1.55, more preferably equal to or more than 1.45 and equal to or less than 1.54, and even more preferably equal to or more than 1.48 and equal to or less than 1.53.

The refractive index of the resin (F) having a norbornene skeleton means a refractive index measured under the conditions of 23° C. and 589 nm using an Abbe refractometer.

From the viewpoint of further suppressing thermal contraction of the optical waveguide, the weight average molecular weight (Mw) of the resin (F) having a norbornene skeleton is preferably equal to or more than 5,000, more preferably equal to or more than 6,000, and even more preferably equal to or more than 7,000, and from the viewpoint of further improving the solubility in an organic solvent, the weight average molecular weight (Mw) is preferably equal to or less than 200,000, more preferably equal to or less than 100,000, and even more preferably equal to or less than 70,000, whereas from the viewpoint of further suppressing thermal contraction of the optical waveguide and further improving the solubility in an organic solvent, the weight average molecular weight (Mw) is preferably equal to or more than 5,000 and equal to or less than 200,000, more preferably equal to or more than 6,000 and equal to or less than 100,000, and even more preferably equal to or more than 7,000 and equal to or less than 70,000.

The weight average molecular weight (Mw) of the resin (F) having a norbornene skeleton can be determined by a gel permeation chromatography (GPC) method using polystyrene as a standard substance.

The resin (F) having a norbornene skeleton can be manufactured by, for example, a known method, and more specifically, can be manufactured by polymerizing monomers capable of forming each structural unit by any method.

### <Other Components>

The resin composition of the present embodiment may further contain, for example, a curing aid, a leveling agent, a colorant, a storage stabilizer, a plasticizer, a filler, inorganic particles, a deterioration inhibitor, a wettability improver, and an antistatic agent. The content of the other components is an appropriate amount.

In a case where the resin composition of the present embodiment contains a thermal cationic polymerization initiator, the resin composition does not have to contain a photosensitizer such as a photocationic polymerization initiator. In a case where the resin composition of the present embodiment contains a thermal cationic polymerization initiator, the content of the photosensitizer in the resin composition of the present embodiment is not particularly limited; however, when the total content of the resin components in the resin composition is set to 100 parts by mass, the content is, for example, less than 1.0 part by mass, and may be less than 0.5 parts by mass, may be less than 0.3 parts by mass, may be less than 0.1 parts by mass, or may be 0.0 parts by mass.

From the viewpoint of further improving the heat resistance of the resin composition, when the total content of the non-volatile components in the resin composition is set to 100% by mass, the content of the (meth)acrylic resin in the resin composition of the present embodiment is preferably less than 50% by mass, more preferably less than 30% by mass, even more preferably less than 10% by mass, still more preferably less than 5% by mass, even more preferably less than 1% by mass, still more preferably less than 0.1% by mass, and even more preferably 0% by mass.

Here, the (meth)acrylic resin is a concept including both a methacrylic resin and an acrylic resin.

From the viewpoint of further improving the embedding properties, when the total content of the resin components in the resin composition is set to 100% by mass, the total content of the polyimide resin (A) and the compound (B) having a cyclic ether structure in the resin composition of the present embodiment is preferably equal to or more than 80% by mass, more preferably equal to or more than 85% by mass, even more preferably equal to or more than 90% by mass, still more preferably equal to or more than 95% by mass, even more preferably equal to or more than 98% by mass, and still more preferably 100% by mass.

When the total content of all the components in the resin composition is set to 100% by mass, the total content of the polyimide resin (A) and the compound (B) having a cyclic ether structure in the resin composition of the present embodiment is preferably equal to or more than 10% by mass, more preferably equal to or more than 20% by mass, even more preferably equal to or more than 30% by mass, still more preferably equal to or more than 35% by mass, even more preferably equal to or more than 50% by mass, still more preferably equal to or more than 70% by mass, even more preferably equal to or more than 80% by mass, still more preferably equal to or more than 85% by mass, even more preferably equal to or more than 90% by mass, and still more preferably equal to or more than 95% by mass, and the upper limit value is not particularly limited, but is, for example, equal to or less than 99% by mass.

When the total content of all the components in the resin composition is set to 100% by mass, the total content of the polyimide resin (A), the compound (B) having a cyclic ether structure, the curing agent (C), the surfactant (D), and the organic solvent (E) in the resin composition of the present embodiment is preferably equal to or more than 50% by mass, more preferably equal to or more than 60% by mass, even more preferably equal to or more than 70% by mass, still more preferably equal to or more than 80% by mass, even more preferably equal to or more than 90% by mass, still more preferably equal to or more than 95% by mass, and even more preferably 100% by mass.

From the viewpoint of further improving the embedding properties, when the total content of the resin components in the resin composition is set to 100% by mass, the total content of the resin (F) having a norbornene skeleton and the compound (B) having a cyclic ether structure in the resin composition of the present embodiment is preferably equal to or more than 80% by mass, more preferably equal to or more than 85% by mass, even more preferably equal to or more than 90% by mass, still more preferably equal to or more than 95% by mass, even more preferably equal to or more than 98% by mass, and still more preferably 100% by mass.

When the total content of all the components in the resin composition is set to 100% by mass, the total content of the resin (F) having a norbornene skeleton and the compound (B) having a cyclic ether structure in the resin composition of the present embodiment is preferably equal to or more than 10% by mass, more preferably equal to or more than 20% by mass, even more preferably equal to or more than 30% by mass, and still more preferably equal to or more than 35% by mass, and is even more preferably equal to or more than 50% by mass, still more preferably equal to or more than 70% by mass, even more preferably equal to or more than 80% by mass, still more preferably equal to or more than 85% by mass, even more preferably equal to or more than 90% by mass, and still more preferably equal to or more than 95% by mass, and the upper limit value is not particularly limited, but is, for example, equal to or less than 99% by mass.

When the total content of all the components in the resin composition is set to 100% by mass, the total content of the resin (F) having a norbornene skeleton, the compound (B) having a cyclic ether structure, the curing agent (C), the surfactant (D), and the organic solvent (E) in the resin composition of the present embodiment is preferably equal to or more than 50% by mass, more preferably equal to or more than 60% by mass, even more preferably equal to or more than 70% by mass, still more preferably equal to or more than 80% by mass, even more preferably equal to or more than 90% by mass, still more preferably equal to or more than 95% by mass, and even more preferably 100% by mass.

### [Method for Manufacturing Resin Composition]

The resin composition of the present embodiment is obtained by, for example, mixing each of the components.

A film-like resin composition of the present embodiment is obtained by, for example, applying a varnish-like resin composition on a base material film and drying the varnish-like resin composition.

### [Film]

A film of the present embodiment is a film that can be used for an optical waveguide cladding and includes a resin layer, in which a flow ratio of the resin layer, which is calculated by Method 2, is equal to or more than 6% and equal to or less than 200%.

### Method 2

A sample is formed such that the thickness of the resin layer is 100 μm, and the sample is cut into a circle having a diameter of 1 cm to obtain a sample for measuring a flow ratio. The sample for measuring a flow ratio is sandwiched between slide glasses and laminated using a laminating machine under conditions of a temperature of 100° C., a pressure of 5.0 MPa, and a time of 180 seconds. Areas of the resin layer before and after lamination are measured, and the flow ratio [%] is calculated from the following Expression (I).

$$Flow ratio [ \% ] = [ ( Area of resin layer after lamination - Area of resin layer before lamination ) / Area of resin layer before lamination ] \times 100 \qquad ( I )$$

Here, the method for forming a sample such that the thickness of the resin layer in Method 2 is 100 μm is not particularly limited, and examples thereof include a method of obtaining a sample by laminating films using a laminating machine such that the thickness of the resin layer is 100 μm. Furthermore, in a case where the thickness of the resin layer is more than 100 μm, a sample can also be obtained by cutting the resin layer such that the thickness of the resin layer is 100 μm.

Among these, as a method for forming a sample such that the thickness of the resin layer in Method 2 is 100 μm, the method described in the Examples is preferred.

As described above, there is a demand for a film that makes it possible to obtain an optical waveguide cladding with improved embedding properties.

Here, the present inventors found for the first time that the embedding properties are improved by setting the flow ratio of the film calculated by Method 2 to a specific range.

In the film of the present embodiment, from the viewpoint of further improving the embedding properties, the flow ratio of the resin layer calculated by Method 2 is preferably equal to or more than 10%, more preferably equal to or more than 13%, even more preferably equal to or more than 15%, and still more preferably equal to or more than 18%, and from the viewpoint of preventing contamination when manufacturing an optical waveguide, and adjusting the thickness of the cladding layer of an optical waveguide to an appropriate thickness, the flow ratio is preferably equal to or less than 190%, more preferably equal to or less than 180%, even more preferably equal to or less than 150%, still more preferably equal to or less than 100%, even more preferably equal to or less than 90%, still more preferably equal to or less than 80%, and even more preferably equal to or less than 70%.

In the film of the present embodiment, the flow ratio of the resin layer can be adjusted to a desired numerical value range by adjusting the type, weight average molecular weight (Mw), and glass transition temperature of the resin constituting the resin layer, the content proportions of the constituent components of the resin layer, and the like.

In the film of the present embodiment, the storage elastic modulus E′ at 100° C. of a cured product obtained by curing the resin layer is preferably equal to or more than 0.5 GPa, more preferably equal to or more than 0.8 GPa, even more preferably equal to or more than 1.0 GPa, still more preferably equal to or more than 1.2 GPa, even more preferably equal to or more than 1.5 GPa, and still more preferably equal to or more than 1.7 GPa, and from the viewpoint of further improving the embedding properties, the storage elastic modulus E′ is preferably equal to or less than 5.0 GPa, more preferably equal to or less than 4.5 GPa, even more preferably equal to or less than 4.0 GPa, still more preferably equal to or less than 3.5 GPa, and even more preferably equal to or less than 3.2 GPa.

In the film of the present embodiment, from the viewpoint of further suppressing thermal contraction of the optical waveguide, the storage elastic modulus E′ at 200° C. of a cured product obtained by curing the resin layer is preferably equal to or more than 0.1 GPa, more preferably equal to or more than 0.2 GPa, and even more preferably equal to or more than 0.3 GPa, and the upper limit value is not particularly limited, but may be, for example, equal to or less than 3.0 GPa, and may be equal to or less than 2.0 GPa.

In the film of the present embodiment, the storage elastic moduli E′ at 100° C. and 200° C. of a cured product obtained by curing the resin layer can be adjusted to desired numerical value ranges by, for example, adjusting the type, weight average molecular weight (Mw), and glass transition temperature of the resin constituting the resin layer, the content proportions of the constituent components of the resin layer, and the like.

In the film of the present embodiment, from the viewpoint of further suppressing thermal contraction of the optical waveguide, the glass transition temperature (Tg) of a cured product obtained by curing the resin layer is preferably equal to or higher than 150° C., more preferably equal to or higher than 160° C., and even more preferably equal to or higher than 180° C., and the upper limit value is not particularly limited, but is, for example, equal to or lower than 400° C.

Here, the glass transition temperature (Tg) means a glass transition temperature calculated from a top peak of tan δ by a dynamic viscoelasticity analyzer (DMA).

The storage elastic modulus E′ at 100° C., the storage elastic modulus E′ at 200° C., and the glass transition temperature (Tg) of a cured product obtained by curing the resin layer of the above-mentioned film can be calculated by the methods described in the Examples.

Specifically, a cured product obtained by curing the resin layer is heated from 30° C. to 400° C. using a dynamic viscoelasticity analyzer in a nitrogen atmosphere under the conditions of a frequency of 1 Hz, tensile mode, a distance between samples of 1 cm, a sample width of 1 cm, and a temperature increase rate of 5° C./min, and the storage elastic modulus E′ and tan δ with respect to temperature are measured. The storage elastic moduli E′ at 100° C. and 200° C. of a cured product obtained by curing the resin layer are calculated from the obtained storage elastic modulus E′. Furthermore, the glass transition temperature (Tg) of the cured product obtained by curing the resin layer is calculated from the obtained top peak of tan δ.

Here, the cured product obtained by curing the resin layer means a cured product in a state in which the resin composition constituting the resin layer is completely cured (C stage).

As a method for determining whether a cured product is in a state in which the resin composition is completely cured (C stage), for example, a method of checking, by Fourier transform infrared spectroscopy (FT-IR method), whether an increase or decrease in the intensity of a peak originating from a functional group involved in a curing reaction (for example, a CO group in a cyclic ether structure) is constant, may be mentioned.

The method of curing the resin layer is not particularly limited, and examples thereof include a method of heating the resin layer, a method of irradiating the resin layer with light, and a method of irradiating the resin layer with light while heating the resin layer; however, preferred is a method of heating the resin layer in the atmosphere at 180° C. for 2 hours. Furthermore, the method of irradiating the resin layer with light is preferably a method of exposing the resin layer to light using a high-pressure mercury lamp under the conditions of a cumulative light amount of 1,000 mJ/cm².

In the film of the present embodiment, the resin layer is preferably formed from the resin composition of the present embodiment.

The resin layer of the present embodiment is preferably a semi-cured product or an uncured product, and more preferably a semi-cured product.

From the viewpoint of further improving the embedding properties, the thickness of the resin layer of the present embodiment is preferably equal to or more than 1 μm, more preferably equal to or more than 5 μm, even more preferably equal to or more than 10 μm, still more preferably equal to or more than 15 μm, and even more preferably equal to or more than 20 μm, and from the viewpoint of further improving the optical propagation efficiency of the optical waveguide, the thickness is preferably equal to or less than 150 μm, more preferably equal to or less than 100 μm, even more preferably equal to or less than 50 μm, still more preferably equal to or less than 40 μm, and even more preferably equal to or less than 30 μm.

The film of the present embodiment is preferably a dry film.

From the viewpoint of further improving the handleability of the film, the thickness of the film of the present embodiment is preferably equal to or more than 10 μm, more preferably equal to or more than 30 μm, even more preferably equal to or more than 50 μm, still more preferably equal to or more than 80 μm or more, and even more preferably 100 μm or more, and is preferably equal to or less than 500 μm, more preferably equal to or less than 300 μm, even more preferably equal to or less than 200 μm, still more preferably equal to or less than 150 μm, and even more preferably equal to or less than 130 μm.

It is preferable that the film of the present embodiment further includes a base material film, and a resin layer is provided on the base material film.

As the base material film, for example, a resin film can be used.

The resin constituting the base material film is not particularly limited; however, it is preferable that the resin includes at least one kind or two or more kinds selected from the group consisting of polyimide and polyethylene terephthalate.

From the viewpoint of further improving the handleability of the film, the thickness of the base material film of the present embodiment is preferably equal to or more than 10 μm, more preferably equal to or more than 15 μm, even more preferably equal to or more than 20 μm, preferably equal to or more than 30 μm, and is preferably equal to or less than 100 μm, more preferably equal to or less than 80 μm, even more preferably equal to or less than 60 μm, and still more preferably equal to or less than 40 μm.

The base material film of the present embodiment may be subjected to a surface treatment such as an antistatic treatment or a release treatment.

The film of the present embodiment may further include a cover film. It is preferable that the cover film is provided so as to be in direct contact with the resin layer.

In a case where the film of the present embodiment includes a base material film, it is preferable that the cover film is provided on a surface of the resin layer on the opposite side of the base material film.

The cover film is not particularly limited, and for example, an OPP cover film can be used.

The film of the present embodiment is obtained by, for example, applying a varnish-like resin composition of the present embodiment on a base material film and drying the resin composition. Examples of the method of applying the resin composition include a method of directly applying using various coating devices such as a pin coater, a die coater, a comma coater, and a curtain coater, and a printing method such as screen printing.

### [Film Set]

A film set of the present embodiment includes a first film and a second film, and at least one of the first film and the second film is the film of the present embodiment.

In the film set of the present embodiment, it is preferable that both the first film and the second film are the films of the present embodiment.

### [Optical Waveguide]

An optical waveguide of the present embodiment will be described using FIG. 1.

The optical waveguide 100 of the present embodiment is an optical waveguide in which a first cladding layer 20, a core layer 30, and a second cladding layer 40 are laminated in this order, in which at least one of the first cladding layer 20 and the second cladding layer 40 contains the resin composition of the present embodiment.

In the optical waveguide of the present embodiment, it is preferable that both the first cladding layer 20 and the second cladding layer 40 contain the resin composition of the present embodiment.

The resin composition of the present embodiment contained in at least one of the first cladding layer 20 and the second cladding layer 40, may be a cured product, may be a semi-cured product, or may be an uncured product, but is preferably a cured product.

In a case where the optical waveguide 100 is provided on the substrate 110, it is preferable that the first cladding layer 20 is on the substrate 110 side.

In a case where the first cladding layer 20 is on the substrate 110 side, preferred thicknesses of the first cladding layer 20 and the second cladding layer 40 are as follows.

From the viewpoint of further improving the embedding properties, the thickness of the first cladding layer 20 is preferably equal to or more than 1 μm, more preferably equal to or more than 3 μm, even more preferably equal to or more than 5 μm, still more preferably equal to or more than 8 μm, even more preferably equal to or more than 10 μm, still more preferably equal to or more than 15 μm, and even more preferably equal to or more than 20 μm, and from the viewpoint of further improving the optical propagation efficiency of the optical waveguide, the thickness is preferably equal to or less than 150 μm, more preferably equal to or less than 100 μm, even more preferably equal to or less than 70 μm, still more preferably equal to or less than 50 μm, even more preferably equal to or less than 40 μm, and still more preferably equal to or less than 30 μm.

From the viewpoint of further suppressing thermal contraction of the optical waveguide, the thickness of the second cladding layer 40 is preferably equal to or more than 1 μm, more preferably equal to or more than 3 μm, even more preferably equal to or more than 5 μm, and still more preferably equal to or more than 8 μm, and is preferably equal to or less than 150 μm, more preferably equal to or less than 100 μm, even more preferably equal to or less than 70 μm, still more preferably equal to or less than 50 μm, even more preferably equal to or less than 40 μm, still more preferably equal to or less than 30 μm, and even more preferably equal to or less than 20 μm.

The material that forms the core layer 30 is not particularly limited, but is formed from, for example, a resin composition.

As a resin for forming the core layer 30, for example, a resin used for the core of a known optical waveguide can be used; however, it is preferable that the resin contains a cyclic olefin-based resin, and it is more preferable that the resin contains a norbornene-based resin.

The resin composition for forming the core layer 30 may contain an antioxidant, a photoacid generator, and the like.

The thickness of the core layer 30 is preferably equal to or more than 1 μm, more preferably equal to or more than 5 μm, even more preferably equal to or more than 10 μm, still more preferably equal to or more than 20 μm, and even more preferably equal to or more than 30 μm, and is preferably equal to or less than 100 μm, more preferably equal to or less than 80 μm, even more preferably equal to or less than 60 μm, and still more preferably equal to or less than 50 μm.

A waveguide pattern may be formed on the core layer 30. Examples of a method of forming the waveguide pattern include an exposure method, an etching method, and a replication method.

In the optical waveguide 100, mirrors may be formed, and a mirror 50 on the light emitting element side and a mirror 60 on the light receiving element side may be formed. Examples of the method of forming the mirror include a method of forming an inclined surface by laser processing or the like.

The optical waveguide 100 may include other layers in addition to the first cladding layer 20, the core layer 30, and the second cladding layer 40, as long as the other layers do not affect the satisfactory performance of the optical waveguide 100.

### [Opto-Electric Composite Substrate]

An opto-electric composite substrate of the present embodiment will be described using FIG. 1.

The opto-electric composite substrate 200 includes a substrate 110 and an optical waveguide 100 provided on the substrate 110.

Examples of the substrate 110 include a printed substrate and a flexible substrate, and a flexible substrate is preferred.

The substrate 110 may have vias 140 formed therein.

The opto-electric composite substrate 200 may include a light emitting element 120, a light receiving element 130, and the like.

The opto-electric composite substrate 200 is obtained by, for example, (i) forming the first cladding layer 20 on the substrate 110, (ii) forming the core layer 30 on the first cladding layer 20, and (iii) forming the second cladding layer 40 on the core layer 30.

Examples of the method of forming each layer include a method of sequentially laminating each layer by laminating films for forming each layer by roll lamination, vacuum roll lamination, flat plate lamination, vacuum flat plate lamination, atmospheric pressure pressing, vacuum pressing, or the like.

### [Electronic Component]

An electronic component of the present embodiment includes the opto-electric composite substrate of the present embodiment.

Examples of the electronic component of the present embodiment include electronic components in electronic devices such as a mobile phone, a game machine, a router device, a WDM device, a personal computer, a television, and a home server.

Thus, the embodiments of the present invention have been described above; however, these are only examples of the present invention, and various configurations other than the above-described ones can be employed.

The present invention is not intended to be limited to the above-described embodiments, and modifications, improvements, and the like made to the extent that the object of the present invention can be achieved are included in the present invention.

### EXAMPLES

Hereinafter, the present embodiment will be described in detail based on Examples and Comparative Examples. The present embodiment is not limited in any way to the description of these Examples.

### [Raw Material]

First, raw materials used in Examples and Comparative Examples will be described.

### Synthesis of Polyimide Resin

### Synthesis of Polyimide Resin (A-1)

67.3 g (0.210 mol) of 2,2′-bis(trifluoromethyl)-4,4′-diaminobiphenyl, 97.7 g (0.220 mol) of 4,4′-(hexafluoroisopropylidene)diphthalic dianhydride, and 495 g of dimethylacetamide were introduced into a 3-L glass separable flask equipped with a stirring device and a stirring blade, and the mixture was stirred and dissolved. In addition, stirring was continued for 12 hours at room temperature under a nitrogen gas stream to perform a polymerization reaction, and a polyamic acid solution was obtained.

16 g of pyridine was added to the obtained polyamic acid solution, and then 82 g of acetic anhydride was added dropwise thereto at room temperature. Thereafter, the liquid temperature was further maintained at 20° C. to 100° C., stirring was continued for 24 hours to perform an imidization reaction, and a polyimide solution was obtained.

The obtained polyimide solution was charged into 1,000 g of methanol while stirring in a container having a volume of 5 L to precipitate a polyimide resin. Thereafter, the solid polyimide resin was separated by filtration using a suction filtration device, and further washed using 1,000 g of methanol. Then, the mixture was dried at 100° C. for 24 hours using a vacuum dryer and further dried at 200° C. for 3 hours to obtain a powdery polyimide resin (A-1).

The weight average molecular weight (Mw) of the polyimide resin (A-1) obtained by GPC measurement was 51,000. The polyimide resin (A-1) was subjected to 1H-NMR measurement, the imidization ratio was calculated from the quantitative value of the amide peak with respect to the peak of the aromatic ring of the polyimide, and as a result, the imidization ratio was equal to or more than 99%.

Furthermore, the polyimide resin (A-1) was dissolved in propylene glycol monomethyl ether acetate such that the solid content concentration was 25%, subsequently the solution was applied using an applicator so as to obtain a film thickness of 30 μm, and further dried in an oven at 100° C. for 10 minutes to obtain a polyimide coating film. The refractive index of the obtained coating film was measured using an Abbe refractometer (manufactured by Atago Co., Ltd., product name: NAR-1T SOLID) under the conditions of 23° C. and 589 nm, and as a result, the refractive index of the polyimide was 1.54.

### Synthesis of Polyimide Resin (A-2)

A polymer synthesis was carried out in the same manner as in the synthesis of the polyimide resin (A-1), except that the amount of 2,2′-bis(trifluoromethyl)-4,4′-diaminobiphenyl in the synthesis of the polyimide resin (A-1) was changed to 68.9 g (0.215 mol), and a polyimide resin (A-2) was obtained.

The weight average molecular weight (Mw) of the polyimide resin (A-2) obtained by GPC measurement was 101,000, the imidization ratio of the polyimide resin (A-2) obtained by NMR measurement was equal to or more than 99%, and the refractive index of the polyimide resin (A-2) obtained by measurement with an Abbe refractometer under the conditions of 23° C. and 589 nm was 1.54.

### Synthesis of Polyimide Resin (A-3)

A polymer synthesis was carried out in the same manner as in the synthesis of the polyimide resin (A-1), except that 57.6 g (0.180 mol) of 2,2′-bis(trifluoromethyl)-4,4′-diaminobiphenyl and 15.6 g (0.030 mol) of 2,2-bis[4-(4-aminophenoxy)phenyl]-1,1,1,3,3,3-hexafluoropropane were used instead of 67.3 g (0.210 mol) of 2,2′-bis(trifluoromethyl)-4,4′-diaminobiphenyl in the synthesis of the polyimide resin (A-1), and a polyimide resin (A-3) was obtained.

The weight average molecular weight (Mw) of the polyimide resin (A-3) obtained by GPC measurement was 48,000, the imidization ratio of the polyimide resin (A-3) obtained by NMR measurement was equal to or more than 99%, and the refractive index of the polyimide resin (A-3) obtained by measurement with an Abbe refractometer under the conditions of 23° C. and 589 nm was 1.55.

### Synthesis of Polyimide Resin (A-4)

A polymer synthesis was carried out in the same manner as in the synthesis of the polyimide resin (A-1), except that 88.85 g (0.200 mol) of 4,4′-(hexafluoroisopropylidene)diphthalic dianhydride and 6.20 g (0.020 mol) of 4,4′-oxydiphthalic dianhydride were used instead of 97.7 g (0.220 mol) of 4,4′-(hexafluoroisopropylidene)diphthalic dianhydride in the synthesis of the polyimide resin (A-1), and a polyimide resin (A-4) was obtained.

The weight average molecular weight (Mw) of the polyimide resin (A-4) obtained by GPC measurement was 49,000, the imidization ratio of the polyimide resin (A-4) obtained by NMR measurement was equal to or more than 99%, and the refractive index of the polyimide resin (A-4) obtained by measurement with an Abbe refractometer under the conditions of 23° C. and 589 nm was 1.55.

### Synthesis of Resin (A-6) having Norbornene Skeleton

A reaction vessel equipped with a stirrer and a cooling tube was prepared, the inside was first thoroughly purged with nitrogen, and then 124.8 g (0.7 mol) of n-hexyl norbornene, 54.1 g (0.3 mol) of 2-[(bicyclo[2.2.1]hept-5-en-2-ylmethoxy)methyl]oxirane, and 440 g of toluene were introduced into the vessel and heated with stirring to 50° C. in an oil bath. A solution obtained by dissolving 9.9 g (0.02 mol) of (toluene) Ni(C₆F₅)₂ in 5 g of toluene was added thereto, and the mixture was further reacted at 50° C. for 3 hours. The obtained solution was reprecipitated in a large amount of methanol to obtain a polymer precipitate, and then the polymer precipitate was separated by filtration with a suction filter to obtain a powder of a polymer. The obtained polymer was vacuum-dried at 60° C. for 16 hours to obtain a resin (A-6) having a norbornene structure. The weight average molecular weight (Mw) of the resin (A-6) having a norbornene structure as obtained by GPC measurement was 50,000, and the refractive index of the resin (A-6) having a norbornene structure as obtained by measurement with an Abbe refractometer under the conditions of 23° C. and 589 nm was 1.50.

### Synthesis of Resin (A-7) Having Norbornene Skeleton

44.6 g (0.25 mol) of n-hexylnorbornene, 45.0 g (0.25 mol) of 2-[(bicyclo[2.2.1]hept-5-en-2-ylmethoxy)methyl]oxirane, 89.6 g (0.50 mol) of N-cyclohexylmaleimide, and 2.3 g (0.01 mol) of dimethyl 2,2′-azobis(2-methyl propionate) were weighed in a reaction vessel having an appropriate size equipped with a stirrer and a cooling tube, and the mixture was dissolved in 263 g of methyl ethyl ketone and 113 g of toluene. Next, dissolved oxygen in the system was removed by nitrogen bubbling, the container was sealed, and the mixture was reacted at 70° C. for 16 hours. The obtained solution was cooled to room temperature and then reprecipitated in a large amount of heptane to obtain a polymer precipitate. Subsequently, the polymer was separated by filtration with a suction filter, and the powder was further washed with heptane and then dried in a dryer at 60° C. for 24 hours to obtain a resin (A-7) having a norbornene skeleton.

The weight average molecular weight (Mw) of the resin (A-7) having a norbornene skeleton as obtained by GPC measurement was 8,500, and the refractive index of the resin (A-7) having a norbornene skeleton as obtained by measurement with an Abbe refractometer under the conditions of 23° C. and 589 nm was 1.51.

The details of raw materials of each component shown in Tables 1, 2, and 4 are as follows.

### <Polymer (A)>

(A-1) Polyimide resin synthesized as described above (Mw=51,000, imidization ratio: equal to or more than 99%, refractive index n=1.54)
(A-2) Polyimide resin synthesized as described above (Mw=101,000, imidization ratio: equal to or more than 99%, refractive index n=1.54)
(A-3) Polyimide resin synthesized as described above (Mw=48,000, imidization ratio: equal to or more than 99%, refractive index n=1.55)
(A-4) Polyimide resin synthesized as described above (Mw=49,000, imidization ratio: equal to or more than 99%, refractive index n=1.55)
(A-5) Rubber-based elastomer (manufactured by Kuraray Co., Ltd., product name: SEPTON Q1250) (Mw=100,000, refractive index n=1.50) (for Comparative Example)
(A-6) Resin having a norbornene structure synthesized as described above (Mw=50,000, refractive index n=1.50)
(A-7) Resin having a norbornene structure synthesized as described above (Mw=8,500, refractive index n=1.51)

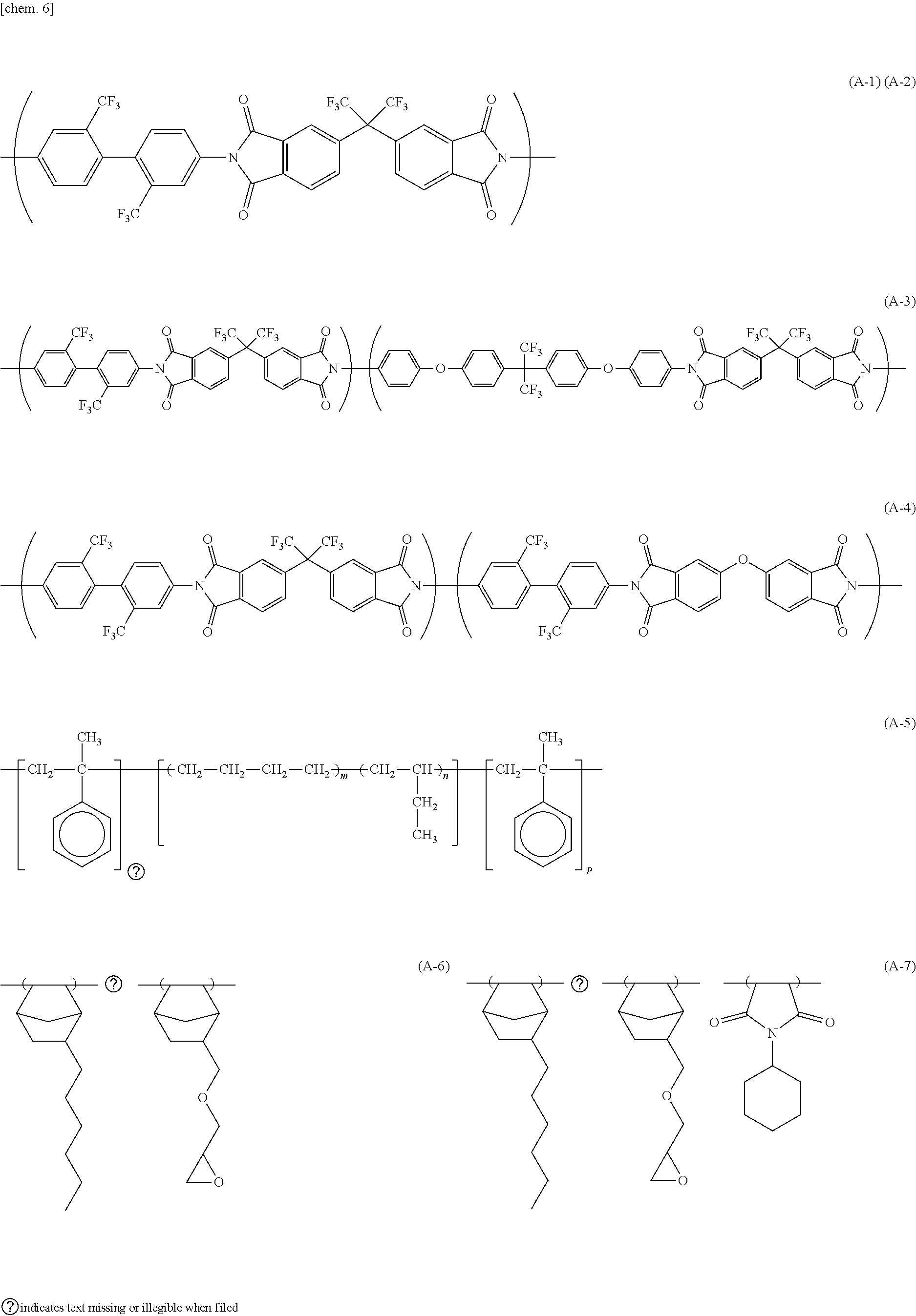

### Compound (B) Having Cyclic Ether Structure

(B-1) CELLOXIDE 2021P (manufactured by Daicel Corporation, epoxy resin having an alicyclic structure, liquid at 23° C., refractive index: 1.51)
(B-2) EHPE-3150 (manufactured by Daicel Corporation, epoxy resin having an alicyclic structure, solid at 23° C., refractive index: 1.51)
(B-3) EPICOTE YX-8000 (manufactured by Mitsubishi Chemical Corporation, epoxy resin having an alicyclic structure, liquid at 23° C., refractive index: 1.51)
(B-4) DENACOL EX-321L (manufactured by Nagase ChemteX Corporation, aliphatic epoxy resin, liquid at 23° C., refractive index: 1.50)
(B-5) OXT-221 (manufactured by TOAGOSEI CO., LTD., oxetane compound, liquid at 23° C., refractive index: 1.50)

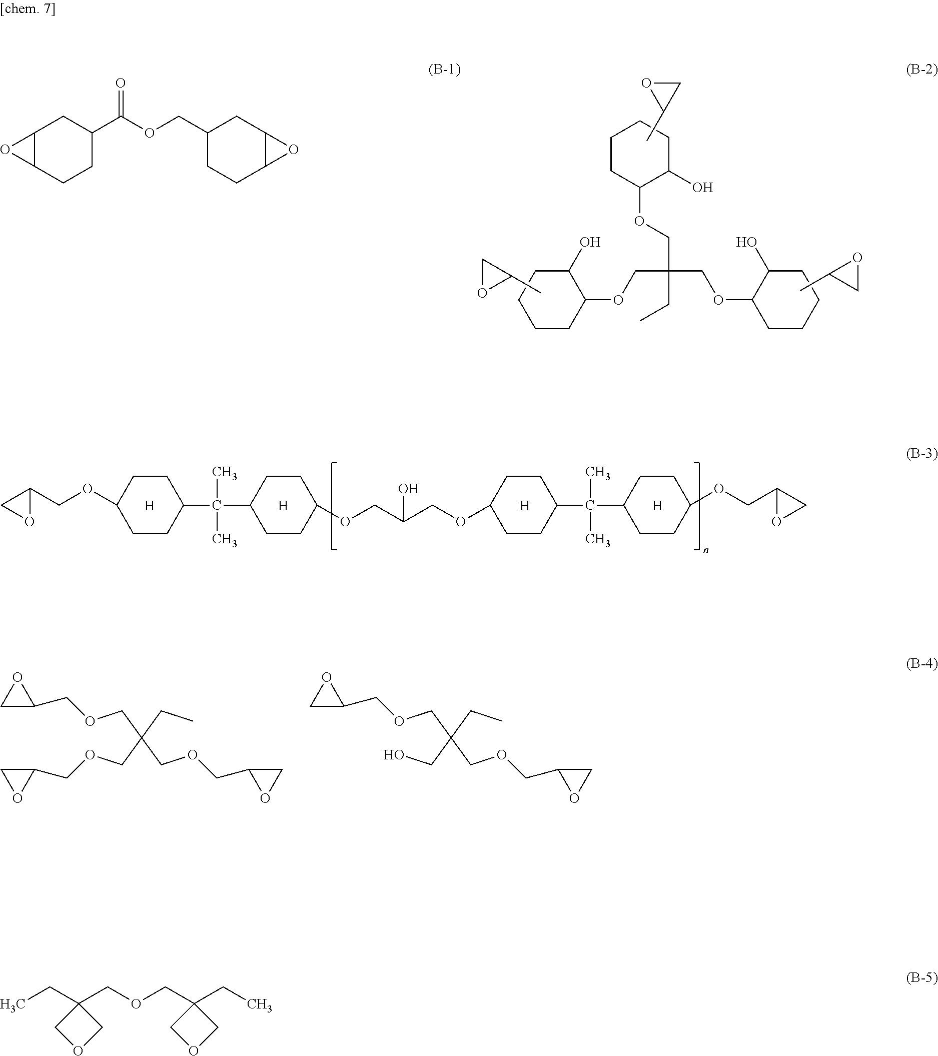

### <Curing Agent (C)>

(C-1) SAN-AID SI-110 (manufactured by SANSHIN CHEMICAL INDUSTRY CO., LTD., thermal cationic polymerization initiator)
(C-2) SAN-AID SI-150 (manufactured by SANSHIN CHEMICAL INDUSTRY CO., LTD., thermal cationic polymerization initiator)
(C-3) SAN-AID SI-B3 (manufactured by SANSHIN CHEMICAL INDUSTRY CO., LTD., thermal cationic polymerization initiator)
(C-4) CUREZOL C11z (manufactured by Shikoku Chemicals Corporation, imidazole-based compound)
(C-5) CPI-310B (manufactured by San-Apro Ltd., photocationic polymerization initiator)

### <Surfactant (D)>

(D-1) BYK-333 (manufactured by BYK-Chemie Japan KK, silicone-based surfactant)
(D-2) BYK-361 (manufactured by BYK-Chemie Japan KK, acrylic polymer-based surfactant) (for Comparative Example)

### <Organic Solvent (E)>

(E-1) Propylene glycol monomethyl ether acetate
(E-2) Propylene glycol monomethyl ether
(E-3) Toluene

### Examples 1 to 9 and 19 to 22, Comparative Examples 1 and 2, and Reference Example 2

### (Preparation of Resin Composition)

Each of the raw materials formulated according to Tables 1, 2, and 4 was stirred at room temperature until the raw materials were completely dissolved, and a solution was obtained. Thereafter, the solution was filtered through a PTFE filter having a pore diameter of 0.2 μm to obtain each of the varnish-like resin compositions of Examples 1 to 9 and 19 to 22, Comparative Examples 1 and 2, and Reference Example 2.

### <Preparation of Film>

The resin compositions of Examples 1 to 9 and 19 to 22, Comparative Examples 1 and 2, and Reference Example 2 obtained in the above-described Preparation of Resin Composition, were each varnish-applied on an antistatic-treated polyethylene terephthalate base material (manufactured by Nippa Corporation, product name: PET38×1-TR1-ASQ) having a thickness of 38 μm, using an applicator such that the thickness after drying was the thickness of the resin layer shown in Tables 1, 2, and 4, and then dried at 100° C. for 10 minutes, finally an OPP cover film (manufactured by Oji F-Tex Co., Ltd., product name: E201F-50 μm) was stuck to the surface on the resin layer side formed from the resin composition to produce a film, and films of Examples 1 to 9 and 19 to 22, and Comparative Examples 1 and 2 were obtained. Incidentally, the resin composition of Reference Example 2 could not form a film.

### Reference Example 1

A varnish-like resin composition of Reference Example 1 formulated according to Table 2 was obtained by the same method as in (Preparation of Resin Composition) in Examples 1 to 9 and 19 to 22, Comparative Examples 1 and 2, and Reference Example 2 described above.

The varnish-like resin composition of Reference Example 1 was varnish-applied on a polyimide base material (manufactured by UBE Corporation, product name: UPILEX 25S) having a thickness of 25 μm, using an applicator so as to have a film thickness after drying of 10 μm, and then dried at 160° C. for 10 minutes, and finally, an OPP cover film (manufactured by Oji F-Tex Co., Ltd., product name: E201F-50 μm) was stuck to the surface on the resin layer side formed from the resin composition to obtain a film of Reference Example 1.

### Examples 10 to 18 and 23, and Comparative Example 3

### (Synthesis of Polymer for Forming Core Layer)

In a glove box in which both moisture and oxygen concentrations were controlled to be equal to or less than 1 ppm and which was filled with dry nitrogen, 7.2 g (40.1 mmol) of hexylnorbornene (HxNB) and 12.9 g (40.1 mmol) of diphenylmethylnorbornene methoxysilane were weighed in a 500-mL vial, 60 g of dehydrated toluene and 11 g of ethyl acetate were added thereto, and the vial was covered with a silicone sealer to tightly seal the top part.

Next, 1.56 g (3.2 mmol) of a Ni catalyst and 10 mL of dehydrated toluene were weighed in a 100-mL vial, a stirrer tip was put into the vial, the vial was tightly sealed, the Ni catalyst was sufficiently stirred to be completely dissolved, and a Ni catalyst solution was obtained. 1 mL of the Ni catalyst solution was accurately weighed with a syringe and quantitatively injected into a vial in which the above-described two kinds of norbornenes were dissolved, the mixture was stirred at room temperature for 1 hour, and a significant increase in viscosity was recognized. At this point, the plug was removed, 60 g of tetrahydrofuran (THF) was added thereto, and the mixture was stirred to obtain a reaction solution.

9.5 g of acetic anhydride, 18 g of aqueous hydrogen peroxide (concentration: 30%), and 30 g of ion-exchanged water were introduced into a 100-mL beaker, and the mixture was stirred to prepare an aqueous solution of peracetic acid. Next, the entire amount of the aqueous solution of peracetic acid was added to the above-described reaction solution, and the mixture was stirred for 12 hours to carry out a reduction treatment of Ni.

Next, the reaction solution after the completion of the treatment was transferred to a separatory funnel, the lower aqueous layer was removed, subsequently 100 mL of a 30% aqueous solution of isopropyl alcohol was added thereto, and then vigorous stirring was performed. The mixture was left to stand to be completely separated into two layers, and then the aqueous layer was removed. After repeating this water washing process three times in total, a polymer generated by adding the oil layer dropwise into an excess amount of acetone was reprecipitated and separated from the filtrate by filtration, and then the solid was heated and dried in a vacuum dryer set at 60° C. for 12 hours to obtain a polymer for forming a core layer.

The molecular weight of the polymer for forming a core layer was measured by GPC and found to be Mw=100,000 and Mn=40,000. Furthermore, as a result of identification by NMR measurement, the molar ratio of each structural unit in the polymer for forming a core layer was 50 mol % of a hexylnorbornene structural unit and 50 mol % of a diphenylmethylnorbornene methoxysilane structural unit.

### (Preparation of Resin Composition for Forming Core Layer)

10 g of the above-described polymer for forming a core layer, which had been purified, was weighed in a 100-mL glass container, 30 g of methylcyclohexane, 0.01 g of a hindered phenol-based antioxidant (manufactured by BASF SE, product name: Irganox 1076), 2.4 g of an oxetane compound (manufactured by TOAGOSEI CO., LTD., product name: OXT-212), 0.8 g of CELLOXIDE 2021P (manufactured by Daicel Corporation), and 0.03 g of a photoacid generator (manufactured by San-Apro Ltd., product name: CPI-310B) were added thereto and uniformly dissolved, subsequently the solution was filtered through a 0.2-μm PTFE filter, and a resin composition for forming a core layer was obtained.

### (Production of Core Layer)

The obtained resin composition for forming a core layer was applied on a PET film that had been subjected to a release treatment, using an applicator such that the film thickness after drying was 40 μm. After the application, the resultant was put into a dryer at 45° C. for 5 minutes, and the solvent was completely removed to obtain a coating film. The obtained coating film was irradiated with ultraviolet radiation at an exposure dose of 100 mJ/cm² using a direct drawing type exposure machine (manufactured by SCREEN Holdings Co., Ltd., product name: LI-9000), and twenty line-and-space patterns having a length of 9 cm and a width of 50 μm were created. Subsequently, the resultant was put into an oven at 150° C. for 30 minutes. When the coating film was taken out from the oven, it was recognized that a clear waveguide pattern (a plurality of core parts) having a rectangular-shaped cross section appeared in the film.

### (Production of Opto-Electric Composite Substrate)

A double-sided copper-clad laminated plate was disposed on a stainless steel plate, and a first cladding layer, a core layer, and a second cladding layer were laminated in this order with a vacuum laminator according to the combinations described in Tables 3 and 5 to obtain a laminated body. At that time, the PET film and the OPP cover film of the base material were removed in a timely manner so that various claddings and the core were in contact with each other, and the dry film of the polyimide base material was used as it was, as the base material of the outermost layer. That is, the layer configuration of the obtained laminated body is “double-sided copper-clad laminated plate/first cladding layer/core layer/second cladding layer/polyimide base material”. The obtained laminated body was heat-treated in an oven under the conditions of 160° C. and 2 hours, and opto-electric composite substrates of Examples 10 to 18 and 23, and Comparative Example 3 were obtained.

### Examples 24 to 26

Opto-electric composite substrates of Examples 24 to 26 were obtained by the same method as in Examples 10 to 18 and 23, and Comparative Example 3, except that the first cladding layer in (Production of Opto-Electric Composite Substrate) in the above-described Examples 10 to 18 and 23, and Comparative Example 3, was laminated with a vacuum laminator, and then the entire first cladding layer was exposed to light from a high-pressure mercury lamp under the conditions of a cumulative light amount of 1000 mJ/cm².

### Evaluation

Hereinafter, evaluation methods for Examples and Comparative Examples will be described.

### <Measurement of Flow Ratio>

The films of Examples 1 to 9 and 19 to 22, and Comparative Examples 1 and 2 were laminated using a laminating machine under the conditions of a temperature of 30° C., a pressure of 1.0 MPa, and a time of 120 seconds such that the thickness of the resin layer formed from the resin composition was 100 μm, to obtain samples. More specifically, two sheets of films were subjected to a lamination treatment to prepare two sheets of films having a thickness of the resin layer of 50 μm, and then the two sheets of films having a thickness of the resin layer of 50 μm were subjected to a lamination treatment to obtain a sample having a thickness of the resin layer of 100 μm. When obtaining a sample, the PET film and the OPP cover film of the base material were appropriately removed. The obtained sample was cut into a circle having a diameter of 1 cm, and a sample for measuring the flow ratio was obtained.

The sample for measuring the flow ratio was sandwiched between slide glasses and laminated using a laminating machine (manufactured by Nikko-Materials Co., Ltd., apparatus name: CVP-600) under the conditions of a temperature of 100° C., a pressure of 5.0 MPa, and a time of 180 seconds. The area of the resin layer before and after lamination was measured, and the flow ratio [%] was calculated from the following Expression (I).

$$Flow ratio [ \% ] = [ ( Area of resin layer after lamination - Area of resin layer before lamination ) / Area of resin layer before lamination ] \times 100 \qquad ( I )$$

### <Measurement of Storage Elastic Modulus E′ and Glass Transition Temperature (Tg) of Cured Product>

### (Production of Sample for DMA Measurement)

### Examples 1 to 9 and 19, and Comparative Examples 1 and 2

The OPP cover film was peeled from the films of Examples 1 to 9 and 19 and Comparative Examples 1 and 2, subsequently two sheets were stacked such that the resin layers formed from the resin composition were facing each other, and the films were laminated under the conditions of a temperature of 100° C., a pressure of 0.5 MPa, and a time of 2 minutes. In addition, the film was cured as it was in an oven at 180° C. for 2 hours in the air atmosphere, and then the base materials on both sides were peeled off to obtain a sample for DMA measurement.

### Examples 20 to 22

A sample for DMA measurement was obtained by the same method as in (Production of Sample for DMA Measurement) in the above-described Examples 1 to 9 and 19 and Comparative Examples 1 and 2, except that the sample was exposed to light after lamination with a high-pressure mercury lamp under the conditions of a cumulative light amount of 1,000 mJ/cm².

### (Measurement of Storage Elastic Modulus E′ and Glass Transition Temperature (Tg))

The obtained sample for DMA measurement was heated from 30° C. to 400° C. in a nitrogen atmosphere using a dynamic viscoelasticity analyzer (manufactured by TA Instruments, Inc., product name: Q800) under the conditions of a frequency of 1 Hz, tensile mode, a distance between samples of 1 cm, a sample width of 1 cm, and a temperature increase rate of 5° C./min, and the storage elastic modulus E′ and tan δ with respect to the temperature were measured. The storage elastic moduli E′ [GPa] at 100° C. and 200° C. of a cured product were read from the obtained storage elastic modulus E′. Furthermore, the glass transition temperature (Tg) [° C.] of the cured product was read from the obtained top peak of tan d.

### <Evaluation of Embedding Properties>

A double-sided copper-clad laminated plate (CCL) having a thickness of 50 μm and having via holes with 100 μmΦ was prepared. The OPP cover film of the films of Examples 1 to 9 and 19 to 22 and Comparative Examples 1 and 2 was peeled off, and the film was stuck onto the CCL such that the resin layer side formed from the resin composition was on the CCL side, and then the lamination was carried out using a laminator under the conditions of a temperature of 100° C., a pressure of 5.0 MPa, and a time of 2 minutes. The via holes of the obtained substrate were observed with a microscope, and a sample in which the via holes were filled without voids was rated as A, a sample in which the via holes were filled with some voids present therein was rated as B, while a sample in which the via holes were not filled was rated as C.

### <Optical Loss Evaluation>

For each of the opto-electric composite substrates of Examples 10 to 18, and 23 to 26 and Comparative Example 3, both sides were cut by dicing such that the length of the patterned part was 7 cm, and a sample for optical loss evaluation was obtained.

For the sample for optical loss evaluation, the propagation loss was evaluated according to 4.6.2.1 Cutback method of “Test Method for Polymer Optical Waveguides (JPCA-PE02-05-01S-2008)”. In the measurement, light having a wavelength of 850 nm was used. From the obtained results, a sample having a propagation loss of less than 1 dB was rated as A, a sample having a propagation loss of 1 dB to 3 dB was rated as B, and a sample having a propagation loss of more than 3 dB was rated as C.

### <Mirror Angle Change Ratio Evaluation>

Mirror processing was performed on the line-and-space of each of the opto-electric composite substrates of Examples 10 to 18 and 23 to 26 and Comparative Example 3 from the polyimide base material side, using an excimer laser (wavelength 193 nm, manufactured by OPTEC S.p.A., product name: ProMaster) by setting the laser intensity to 7 mJ, the laser oscillation frequency to 250 Hz, the opening of a stainless steel mask for cutting the laser light to 1 mm×1 mm, the movement speed of the processing table to 45 μm/s, and the movement distance of the processing table to 150 μm, with the angle being approximately 45 degrees. For the obtained mirrors, the length was measured with a laser microscope, and the mirror angle after processing (angle A) was calculated. Subsequently, the mirror-processed optical waveguide sample was treated three times using an N₂ reflow apparatus at a maximum temperature of 250° C., and the mirror angle (angle B) was measured again. The change ratio of the mirror angle before and after reflow was calculated from the following expression, and a sample with a change ratio of <1% was rated as A, a sample with a change ratio of 1% to 3% was rated as B, while a sample with a change ratio of more than 3% was rated as C.

Mirror angle change ratio [%]=[(Angle A−Angle B)/Angle A]×100

Evaluation results for Examples 1 to 9 and 19 to 22 and Comparative Examples 1 and 2 are respectively shown in Tables 1, 2, and 4. The evaluation results for Examples 10 to 18 and 23 to 26, and Comparative Example 3 are respectively shown in Tables 3 and 5. In the tables, the symbol “-” in the evaluation results means that the measurement was not performed.

TABLE 1

| | | | Example 1 | Example 2 | Example 3 | Example 4 | Example 5 | Example 6 |
|---|---|---|---|---|---|---|---|---|
| | | | Clackling A | Cladding B | Cladding C | Cladding D | Cladkling E | Cladding F |
| Resin | Polymer (A) | (A-1) | 50 | 50 | 40 | 60 | — | — |
| composition | [parts by mass] | (A-2) | — | — | — | — | 50 | — |
| | | (A-3) | — | — | — | — | — | 50 |
| | | (A-4) | — | — | — | — | — | — |
| | | (A-5) | — | — | — | — | — | — |
| | | (A-6) | — | — | — | — | — | — |
| | | (A-7) | — | — | — | — | — | — |
| | Compound (B) having | (B-1) | 50 | 20 | 30 | 10 | 20 | 20 |
| | cyclic ether structure | (B-2) | — | 10 | 20 | — | 10 | 10 |
| | [parts by mass] | (B-3) | — | — | — | — | — | — |
| | | (B-4) | — | 5 | — | 20 | 5 | 5 |
| | | (B-5) | — | 10 | 10 | 10 | 10 | 10 |
| | Curing agent (C) | (C-1) | 1.0 | 1.0 | 1.0 | 1.0 | 1.0 | 1.0 |
| | [parts by mass] | (C-2) | 0.1 | 0.1 | 0.1 | 0.1 | 0.1 | 0.1 |
| | | (C-3) | 0.1 | 0.1 | 0.1 | 0.1 | 0.1 | 0.1 |
| | | (C-4) | — | — | — | — | — | — |
| | | (C-5) | — | — | — | — | — | — |
| | Surfactant (D) | (D-1) | 0.1 | 0.1 | 0.1 | 0.1 | 0.1 | 0.1 |
| | [parts by mass] | (D-2) | — | — | — | — | — | — |
| | Organic solvent (E) | (E-1) | 189 | 180 | 189 | 189 | 180 | 180 |
| | [parts by mass] | (E-2) | 47 | 45 | 47 | 47 | 45 | 45 |
| | | (E-3) | — | — | — | — | — | — |

| Thickness of resin layer [μm] | | 25 | 25 | 25 | 25 | 25 | 25 |
|---|---|---|---|---|---|---|---|
| Evaluation | Flow ratio [%] | 50 | 35 | 60 | 20 | 45 | 40 |
| results | Storage elastic modulus E′ at | 3.0 | 2.7 | 2.2 | 2.9 | 2.8 | 2.8 |
| | 100° C. of cured product [GPa] | | | | | | |
| | Storage elastic modulus E′ at | 1.5 | 0.7 | 0.6 | 1.2 | 0.8 | 0.8 |
| | 200° C. of cured product [GPa] | | | | | | |
| | Glass transition temperature Tg of | 230 | 200 | 250 | 220 | 230 | 210 |
| | cured product [° C.] | | | | | | |
| | Evaluation of embedding properties | A | A | A | A | A | A |

TABLE 2

| | | | | | | Comparative | Comparative | Reference | Reference |
|---|---|---|---|---|---|---|---|---|---|
| | | | Example 7 | Example 8 | Example 9 | Example 1 | Example 2 | Example 1 | Example 2 |
| | | | Cladkling G | Cladling H | Cladding I | Cladding J | Cladding K | Cladding L | Cladding M |
| Resin | Polymer (A) | (A-1) | — | 50 | 30 | — | 100 | 30 | — |
| composition | [parts by mass] | (A-2) | — | — | — | — | — | — | — |
| | | (A-3) | — | — | — | — | — | — | — |
| | | (A-4) | 50 | — | — | — | — | — | — |
| | | (A-5) | — | — | — | 80 | — | — | — |
| | | (A-6) | — | — | — | — | — | — | — |
| | | (A-7) | — | — | — | — | — | — | — |
| | Carpound (B) | (B-1) | 20 | 40 | — | 20 | — | — | 30 |
| | having cyclic | (B-2) | 10 | — | 30 | — | — | 30 | 20 |
| | ether structure | (B-3) | — | — | 30 | — | — | 30 | — |
| | [parts by mass] | (B-4) | 5 | — | 10 | — | — | 10 | — |
| | | (B-5) | 10 | 10 | — | — | — | — | — |
| | Curing agent | (C-1) | 1.0 | — | — | 1.0 | 1.0 | — | 1.0 |
| | (° C.) | (C-2) | 0.1 | — | — | — | 0.1 | — | 0.1 |
| | [parts by mass] | (C-3) | 0.1 | — | — | — | 0.1 | — | 0.1 |
| | | (C-4) | — | 5.0 | 5.0 | — | — | 5.0 | — |
| | | (C-5) | — | — | — | — | — | — | — |
| | Surfactant (D) | (D-1) | 0.1 | 0.1 | 0.1 | — | 0.1 | 0.1 | 0.1 |
| | [parts by mass] | (D-2) | — | — | — | 3.0 | — | — | — |
| | Organic | (E-1) | 180 | 196 | 196 | — | 189 | 196 | 96 |
| | solvent (E) | | | | | | | | |
| | [parts by mass] | (E-2) | 45 | 49 | 49 | — | 47 | 49 | 24 |
| | | (E-3) | — | — | — | 236 | — | — | — |

| Thickness of resin layer [μm] | | 25 | 25 | 25 | 25 | 25 | 10 | 25 |
|---|---|---|---|---|---|---|---|---|
| Evaluation | Flow ratio [%] | 40 | 65 | 30 | 5 | 0 | — | — |
| results | Storage elastic | 2.9 | 2.1 | 1.8 | 0.2 | 3.6 | — | — |
| | modulus E′ at 100° C. of | | | | | | | Film cannot |
| | cured product [GPa] | | | | | | | be formed |
| | Storage elastic | 0.8 | 1.2 | 0.4 | <0.05 | 1.5 | — | |
| | modulus E′ at 200° C. of | | | | | | | |
| | cured product [GPa] | | | | | | | |
| | Glass transition | 210 | 190 | 190 | <50 | 400 | — | — |
| | temperature Tg of | | | | | | | |
| | cured product [° C.] | | | | | | | |
| | Evaluation of | A | A | A | B | C | — | — |
| | embedding properties | | | | | | | |

TABLE 3

| | Example | Example | Example | Example | Example | Example | Example | Example | Example | Comparative |
|---|---|---|---|---|---|---|---|---|---|---|
| | 10 | 11 | 12 | 13 | 14 | 15 | 16 | 17 | 18 | Example 3 |
| First clackling | Clackling | Clackling | Clackling | Cladding | Clackling | Clackling | Cladding | Clackling | Cladding | Clackling |
| layer | A | B | C | D | E | F | G | H | I | J |
| Second cladding | Cladkling | Cladkling | Clackling | Clackling | Clackling | Clackling | Cladding | Clackling | Cladding | Clackling |
| layer | L | L | L | L | L | L | L | L | L | L |
| Evaluation of | A | A | A | A | A | A | A | A | A | A |
| optical loss | | | | | | | | | | |
| Evaluation of | A | A | A | A | A | A | A | A | A | C |
| mirror angle | | | | | | | | | | |
| change ratio | | | | | | | | | | |

TABLE 4

| | | | Example | Example | Example | Example |
|---|---|---|---|---|---|---|
| | | | 19 | 20 | 21 | 22 |
| | | | Clackling | Clackling | Cladding | Cladding |
| | | | N | O | P | Q |
| Resin | Polymer (A) | (A-1) | 65 | — | — | — |
| carposition | [parts by mass] | (A-2) | — | — | — | — |
| | | (A-3) | — | — | — | — |
| | | (A-4) | — | — | — | — |
| | | (A-5) | — | — | — | — |
| | | (A-6) | — | 80 | — | — |
| | | (A-7) | — | — | 50 | 40 |
| | Compound (B) | (B-1) | 35 | — | — | — |
| | having cyclic | (B-2) | — | — | — | — |
| | ether structure | (B-3) | — | 20 | 50 | 60 |
| | [parts by mass] | (B-4) | — | — | — | — |
| | | (B-5) | 10 | — | — | — |
| | Curing agent (C) | (C-1) | 1.0 | 1.0 | 1.0 | 1.0 |
| | [parts by mass] | (C-2) | 0.1 | 0.1 | 0.1 | 0.1 |
| | | (C-3) | 0.1 | 0.1 | 0.1 | 0.1 |
| | | (C-4) | — | — | — | — |
| | | (C-5) | — | 0.3 | 0.3 | 0.3 |
| | Surfactant (D) | (D-1) | 0.1 | 0.1 | 0.1 | 0.1 |
| | [parts by mass] | (D-2) | — | — | — | — |
| | Organic solvent (E) | (E-1) | 208 | 190 | 122 | 122 |
| | [parts by mass] | (E-2) | 52 | 47 | 30 | 30 |
| | | (E-3) | — | — | — | — |

| Thickness of resin layer [μm] | | 25 | 25 | 25 | 25 |
|---|---|---|---|---|---|
| Evaluation | Flow ratio [%] | 6 | 45 | 70 | 180 |
| Results | Storage elastic modulus E′ at 100° | 3.1 | 1.2 | 1.3 | 1.2 |
| | C. of cured product [Gpa] | | | | |
| | Storage elastic modulus E′ at 200° | 1.3 | 0.2 | 0.15 | 0.15 |
| | C. of cured product [GPa] | | | | |
| | Glass transition temperature Tg | 230 | 250 | 200 | 170 |
| | of cured product [° C.] | | | | |
| | Evaluation of embedding properties | A | A | A | A |

TABLE 5

| | Example | Example | Example | Example |
|---|---|---|---|---|
| | 23 | 24 | 25 | 26 |
| First cladding layer | Cladding | Cladding | Cladding | Cladding |
| | N | O | P | Q |
| Second cladding layer | Cladding | Cladding | Cladding | Cladding |
| | L | L | L | L |
| Evaluation of optical loss | A | A | A | A |
| Evaluation of mirror | A | A | A | A |
| angle change ratio | | | | |

From Tables 1, 2, and 4, the films of Examples all showed satisfactory evaluation results for the embedding properties. That is, it can be understood that according to the resin composition and the film of the present embodiment, the embedding properties are improved.

Furthermore, from Tables 3 and 5, it was found that the opto-electric composite substrates of Examples had a small mirror angle deformation ratio and could suppress thermal contraction. That is, it can be understood that according to the resin composition and the film of the present embodiment, thermal contraction of the optical waveguide can be suppressed.

This application claims priority on the basis of Japanese Patent Application No. 2023-057397, filed Mar. 31, 2023, the disclosure of which is incorporated herein in its entirety by reference.

### REFERENCE SIGNS LIST

20 first cladding layer
30 core layer
40 second cladding layer
50 mirror on light emitting element side
60 mirror on light receiving element side
100 optical waveguide
110 substrate
120 light emitting element
130 light receiving element
140a, 140b via
200 opto-electric composite substrate

What is claim is:

1-18. (canceled)

19. A resin composition that is usable for an optical waveguide cladding,
wherein a flow ratio of a resin layer formed from the resin composition as calculated by the following Method 1 is equal to or more than 6% and equal to or less than 200%:
[Method 1]
a sample is formed such that a thickness of the resin layer formed from the resin composition is 100 μm, the sample is cut into a circle having a diameter of 1 cm to obtain a sample for measuring a flow ratio,
the sample for measuring a flow ratio is sandwiched between slide glasses and laminated using a laminating machine under conditions of a temperature of 100° C., a pressure of 5.0 MPa, and a time of 180 seconds,
areas of the resin layer before and after lamination are measured, and the flow ratio [%] is calculated from the following Expression (I):
$$Flow ratio [ \% ] = [ ( Area of resin layer after lamination - Area of resin layer before lamination ) / Area of resin layer before lamination ] \times 100. \qquad ( I )$$

20. The resin composition according to claim 19,
wherein a storage elastic modulus E′ at 100° C. of a cured product formed from the resin composition is equal to or more than 0.5 GPa and equal to or less than 5.0 GPa.

21. The resin composition according to claim 19,
wherein a storage elastic modulus E′ at 200° C. of a cured product formed from the resin composition is equal to or more than 0.1 GPa and equal to or less than 3.0 GPa.

22. The resin composition according to claim 19,
wherein a glass transition temperature of a cured product formed from the resin composition, which is calculated from a top peak of tan δ by a dynamic viscoelasticity analyzer (DMA), is equal to or higher than 150° C. and equal to or lower than 400° C.

23. The resin composition according to claim 19, comprising:
a polyimide resin (A); and
a compound (B) having a cyclic ether structure.

24. The resin composition according to claim 19, comprising:
a resin (F) having a norbornene skeleton; and
a compound (B) having a cyclic ether structure.

25. The resin composition according to claim 23, further comprising:
a curing agent (C).

26. A film that is usable for an optical waveguide cladding, the film comprising:
a resin layer,
wherein a flow ratio of the resin layer as calculated by the following Method 2 is equal to or more than 6% and equal to or less than 200%:
[Method 2]
a sample is formed such that a thickness of the resin layer is 100 μm, the sample is cut into a circle having a diameter of 1 cm to obtain a sample for measuring a flow ratio,
the sample for measuring a flow ratio is sandwiched between slide glasses and laminated using a laminating machine under conditions of a temperature of 100° C., a pressure of 5.0 MPa, and a time of 180 seconds,
areas of the resin layer before and after lamination are measured, and the flow ratio [%] is calculated from the following Expression (I):
$$Flow ratio [ \% ] = [ ( Area of resin layer after lamination - Area of resin layer before lamination ) / Area of resin layer before lamination ] \times 100. \qquad ( I )$$

27. The film according to claim 26,
wherein a storage elastic modulus E′ at 100° C. of a cured product obtained by curing the resin layer is equal to or more than 0.5 GPa and equal to or less than 5.0 GPa.

28. The film according to claim 26,
wherein a storage elastic modulus E′ at 200° C. of a cured product obtained by curing the resin layer is equal to or more than 0.1 GPa and equal to or less than 3.0 GPa.

29. The film according to claim 26,
wherein a glass transition temperature of a cured product obtained by curing the resin layer, which is calculated from a top peak of tan δ by a dynamic viscoelasticity analyzer (DMA), is equal to or higher than 150° C. and equal to or lower than 400° C.

30. The film according to claim 26, further comprising:
a base material film,
wherein the resin layer is provided over the base material film.

31. The film according to claim 30,
wherein a resin constituting the base material film contains at least one kind or two or more kinds selected from the group consisting of a polyimide and polyethylene terephthalate.

32. The film according to claim 26,
wherein the film is a dry film.

33. A film set that is usable for an optical waveguide cladding, the film set comprising:
a first film; and
a second film,
wherein at least one of the first film and the second film is the film according to claim 26.

34. An optical waveguide comprising:
a first cladding layer;
a core layer; and
a second cladding layer,
wherein the first cladding layer, the core layer, and the second cladding layer are laminated in this order, and
at least one of the first cladding layer and the second cladding layer contains the resin composition according to claim 19.

35. An opto-electric composite substrate comprising:
a substrate; and
the optical waveguide according to claim 34 provided over the substrate.

36. An electronic component comprising:
an opto-electric composite substrate according to claim 35.

37. The resin composition according to claim 24,
further comprising:
a curing agent (C).
